(19) United States
(12) Patent Application Publication
(10) Pub. No.: US 2026/0006716 A1
(43) Pub. Date: Jan. 1, 2026

(54) ELECTRONIC DEVICE INCLUDING FLEXIBLE PRINTED CIRCUIT BOARD

(71) Applicant: Samsung Electronics Co., Ltd., Suwon-si (KR)

(72) Inventors: Joonyoung SON, Suwon-si (KR); Jinchoul LEE, Suwon-si (KR); Muchang SON, Suwon-si (KR); Juhwan YUN, Suwon-si (KR); Hyunseung YOON, Suwon-si (KR); Junmyeong JEONG, Suwon-si (KR)

(21) Appl. No.: 19/260,982

(22) Filed: Jul. 7, 2025

Related U.S. Application Data
(63) Continuation of application No. PCT/KR2025/007592, filed on Jun. 2, 2025.

(30) Foreign Application Priority Data
Jun. 28, 2024 (KR) 10-2024-0085758
Aug. 21, 2024 (KR) 10-2024-0112152

(51) Int. Cl. H05K 1/02; G02C 11/00

(52) U.S. Cl. CPC H05K 1/028; G02C 11/10; H05K 1/0213; H05K 2201/10128

(57) ABSTRACT

A wearable electronic device is provided. The wearable electronic device includes a frame configured to accommodate at least one lens or at least one display, a temple connected to an end of the frame, and a flexible printed circuit board (FPCB) of which at least a portion is disposed in the temple and extending in a longitudinal direction. The FPCB includes a plurality of substrate layers including at least one circuit line formed on a surface thereof and disposed to overlap in a thickness direction and at least one connecting layer disposed between the plurality of substrate layers and configured to connect surfaces of adjacent substrate layers, wherein the FPCB, when viewed in the thickness direction, includes a first circuit region in which a data line for transmitting a data signal is formed, and the at least one connecting layer is disposed not to overlap the first circuit region.

### CROSS-REFERENCE TO RELATED APPLICATION(S)

This application is a continuation application, claiming priority under 35 U.S.C. § 365 (c), of an International application No. PCT/KR2025/007592, filed on Jun. 2, 2025, which is based on and claims the benefit of a Korean patent application number 10-2024-0085758, filed on Jun. 28, 2024, in the Korean Intellectual Property Office, and of a Korean patent application number 10-2024-0112152, filed on Aug. 21, 2024, in the Korean Intellectual Property Office, the disclosure of each of which is incorporated by reference herein in its entirety.

### BACKGROUND

### 1. Field

The disclosure relates to an electronic device including a flexible printed circuit board (FPCB).

### 2. Description of Related Art

Thanks to advancements in electronics technology, various types of electronic products are being developed and distributed. For example, the distribution of electronic devices that may be worn on the body, such as a wearable electronic device, is increasing.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device including a flexible printed circuit board (FPCB).

Additional aspects will be set forth in part in the description which follows and, in part, will be apparent from the description, or may be learned by practice of the presented embodiments.

In accordance with an aspect of the disclosure, a wearable electronic device is provided. The wearable electronic device includes a frame configured to accommodate at least one lens or at least one display, a temple connected to an end of the frame, and a flexible printed circuit board (FPCB) of which at least a portion is disposed in the temple and extending in a longitudinal direction. The FPCB includes a plurality of substrate layers including at least one circuit line formed on a surface thereof and disposed to overlap in a thickness direction and at least one connecting layer disposed between the plurality of substrate layers and configured to connect surfaces of adjacent substrate layers. The FPCB, when viewed in the thickness direction, includes a first circuit region in which a data line for transmitting a data signal is formed, and the at least one connecting layer is disposed not to overlap the first circuit region.

In accordance with an aspect of the disclosure, a flexible printed circuit board (FPCB) is provided. The FPCB includes a plurality of substrate layers including a circuit line formed on surfaces thereof and disposed to overlap in a thickness direction and at least one connecting layer configured to connect at least a portion of the plurality of substrate layers. Each of the plurality of substrate layers includes a first circuit region including a data line for transmitting a data signal in a longitudinal direction of the FPCB and a second circuit region including a power line for transmitting a power signal in the longitudinal direction of the FPCB. The at least one connecting layer is disposed not to overlap the first circuit region.

In accordance with an aspect of the disclosure, an electronic device is provided. The electronic device includes a housing including a component element disposed therein and a flexible printed circuit board (FPCB) disposed in the housing, electrically connected to the component element, and at least partially bending in a longitudinal direction. The FPCB includes a plurality of substrate layers disposed to overlap in a thickness direction and including a circuit formed on surfaces thereof and at least one connecting layer disposed on at least a portion between the plurality of substrate layers and configured to connect a pair of substrate layers adjacent to one another, wherein, when viewed in the thickness direction, the FPCB includes a first circuit region in which a data line for transmitting a data signal is positioned and a second circuit region in which a power line for transmitting a power signal is positioned. The at least one connecting layer is disposed not to overlap the first circuit region.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a perspective view illustrating an internal configuration of a wearable electronic device according to an embodiment of the disclosure;

FIG. 3A is a diagram illustrating a front surface of a wearable electronic device according to an embodiment of the disclosure;

FIG. 3B is a diagram illustrating a rear surface of the wearable electronic device according to an embodiment of the disclosure;

FIG. 4A is a see-through perspective view of a wearable electronic device according to an embodiment of the disclosure;

FIG. 4B is a side view of a flexible printed circuit board (FPCB) according to an embodiment of the disclosure;

FIG. 4C is a partially enlarged view of the region A of the FPCB of FIG. 4A according to an embodiment of the disclosure;

FIG. 4D is a cross-sectional view of the FPCB taken along the line I-I of FIG. 4C according to an embodiment of the disclosure;

FIG. 4E is a cross-sectional view of the FPCB taken along the line II-II of FIG. 4C according to an embodiment of the disclosure;

FIG. 4F is a cross-sectional view of the FPCB taken along the line I-I of FIG. 4C according to an embodiment of the disclosure;

FIG. 4G is a cross-sectional view of the FPCB taken along the line I-I of FIG. 4C according to an embodiment of the disclosure;

FIG. 4H is a cross-sectional view of the FPCB taken along the line I-I of FIG. 4C according to an embodiment of the disclosure;

FIG. 4I is a cross-sectional view of the FPCB taken along the line I-I of FIG. 4C according to an embodiment of the disclosure;

FIG. 4J is a cross-sectional view of the FPCB taken along the line I-I of FIG. 4C according to an embodiment of the disclosure;

FIG. 5A is a partial perspective view illustrating a bending portion of an FPCB according to an embodiment of the disclosure;

FIG. 5B is a partial perspective view illustrating a bending portion of an FPCB according to an embodiment of the disclosure;

FIG. 5C is a partial perspective view illustrating a bending portion of an FPCB according to an embodiment of the disclosure;

FIG. 6A is a partially enlarged view of an FPCB according to an embodiment of the disclosure;

FIG. 6B is a cross-sectional view of the FPCB taken along the line III-III of FIG. 6A according to an embodiment of the disclosure;

FIG. 6C is a cross-sectional view of an FPCB taken along the line III-III of FIG. 6A according to an embodiment of the disclosure;

FIG. 7A is a partially enlarged view of an FPCB according to an embodiment of the disclosure;

FIG. 7B is a side view of the FPCB according to an embodiment of the disclosure;

FIG. 7C is a cross-sectional view of the FPCB taken along the line IV-IV of FIG. 7A according to an embodiment of the disclosure;

FIG. 7D is a cross-sectional view of the FPCB showing the region D of FIG. 7B according to an embodiment of the disclosure;

FIG. 7E is a cross-sectional view of the FPCB showing the region D of FIG. 7B according to an embodiment of the disclosure;

FIG. 8A is a see-through perspective view of a wearable electronic device according to an embodiment of the disclosure;

FIG. 8B is a partially enlarged view of the region C of an FPCB of FIG. 8A according to an embodiment of the disclosure;

FIG. 8C is a cross-sectional view of the FPCB taken along the line V-V of FIG. 8B according to an embodiment of the disclosure;

FIG. 8D is a partially enlarged view of the region C of the FPCB of FIG. 8A according to an embodiment of the disclosure;

FIG. 8E is a cross-sectional view of the FPCB taken along the line VI-VI of FIG. 8D according to an embodiment of the disclosure.

FIG. 9A is a front perspective view of an electronic device according to an embodiment of the disclosure;

FIG. 9B is a rear view of the electronic device according to an embodiment of the disclosure;

FIG. 9C is an exploded perspective view of the electronic device according to an embodiment of the disclosure;

FIG. 9D is a partial perspective view of an FPCB according to an embodiment of the disclosure;

FIG. 9E is a cross-sectional view of the FPCB taken along the line VII-VII of FIG. 9D according to an embodiment of the disclosure;

FIG. 10A is a front perspective view of an electronic device according to an embodiment of the disclosure;

FIG. 10B is a rear view of the electronic device according to an embodiment of the disclosure;

FIG. 10C is an exploded perspective view of the electronic device according to an embodiment of the disclosure;

FIG. 10D is a perspective view of an FPCB according to an embodiment of the disclosure;

FIG. 10E is a cross-sectional view of the FPCB taken along the line IX-IX of FIG. 10D according to an embodiment of the disclosure;

FIG. 11A is a perspective view illustrating a first state of an electronic device according to an embodiment of the disclosure;

FIG. 11B is a rear view illustrating the first state of the electronic device according to an embodiment of the disclosure;

FIG. 11C is a perspective view illustrating a second state of the electronic device according to an embodiment of the disclosure;

FIG. 11D is a partial perspective view of an FPCB according to an embodiment of the disclosure;

FIG. 11E is a cross-sectional view of the FPCB taken along the line XIe-XIe of FIG. 11D according to an embodiment of the disclosure;

FIG. 12A is a front perspective view illustrating a first state of an electronic device according to an embodiment of the disclosure;

FIG. 12B is a front perspective view illustrating a second state of the electronic device according to an embodiment of the disclosure;

FIG. 12C is a rear perspective view illustrating the first state of the electronic device according to an embodiment of the disclosure;

FIG. 12D is a rear perspective view illustrating the second state of the electronic device according to an embodiment of the disclosure;

FIG. 12E is a side perspective view of the electronic device illustrating an FPCB according to an embodiment of the disclosure;

FIG. 12F is a partial perspective view of the FPCB according to an embodiment of the disclosure; and

FIG. 12G is a cross-sectional view of the FPCB taken along the line XIIg-XIIg of FIG. 12F according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

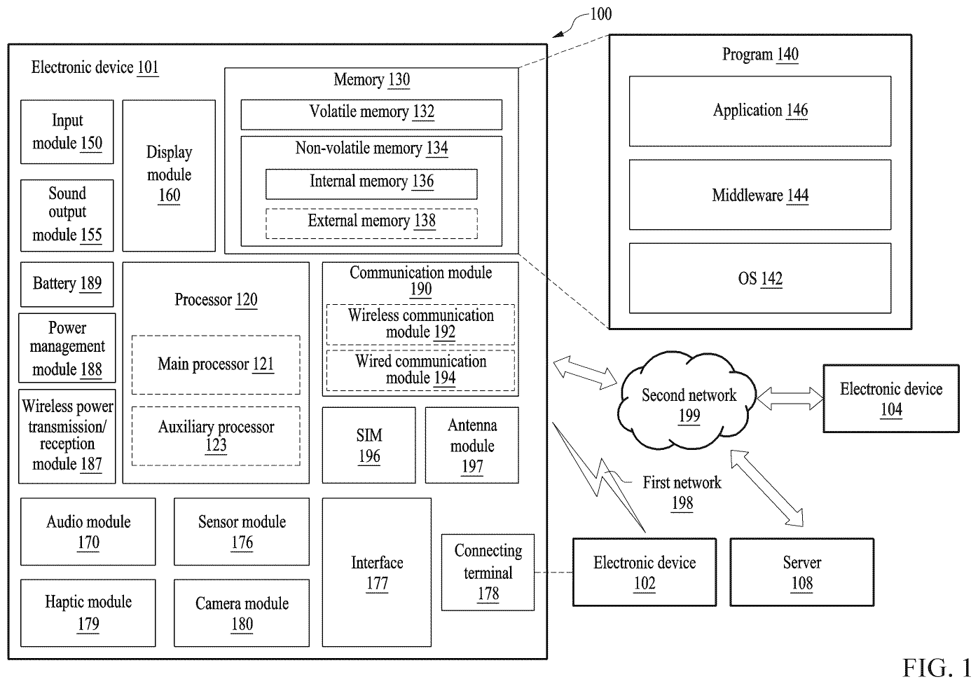

FIG. 1 is a block diagram of an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or communicate with an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a wireless power transmission/reception module 187, a power management module 188, a battery 189, a communication module 190, a subscriber identification module (SIM) 196, or an antenna module 197. In some embodiments, at least one (e.g., the connecting terminal 178) of the components may be omitted from the electronic device 101, or one or more other components may be added to the electronic device 101. In some embodiments, some (e.g., the sensor module 176, the camera module 180, or the antenna module 197) of the components may be integrated as a single component (e.g., the display module 160).

The processor 120 may execute, for example, software (e.g., the program 140) to control at least one other component (e.g., a hardware or software component) of the electronic device 101 connected to the processor 120 and may perform various data processing or computation. According to an embodiment, as at least a portion of data processing or computations, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) that is operable independently of or in conjunction with the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented separately from the main processor 121 or as a portion of the main processor 121.

The auxiliary processor 123 may control at least some of functions or states related to at least one (e.g., the display module 160, the sensor module 176, or the communication module 190) of the components of the electronic device 101, instead of the main processor 121 while the main processor 121 is in an inactive (e.g., sleep) state or along with the main processor 121 while the main processor 121 is an active state (e.g., executing an application). According to an embodiment, the auxiliary processor 123 (e.g., an ISP or a CP) may be implemented as a portion of another component (e.g., the camera module 180 or the communication module 190) that is functionally related to the auxiliary processor 123. According to an embodiment, the auxiliary processor 123 (e.g., an NPU) may include a hardware structure specified for artificial intelligence (AI) model processing. An AI model may be generated through machine learning. Such learning may be performed by, for example, the electronic device 101 in which AI is performed, or performed via a separate server (e.g., the server 108). A learning algorithm may include, but is not limited to, for example, supervised learning, unsupervised learning, semi-supervised learning, or reinforcement learning. The AI model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not limited thereto. The AI model may additionally or alternatively include a software structure other than the hardware structure.

The memory 130 may store various pieces of data used by at least one component (e.g., the processor 120 or the sensor module 176) of the electronic device 101. The data may include, for example, software (e.g., the program 140) and input data or output data for a command related thereto. The memory 130 may include the volatile memory 132 or the non-volatile memory 134.

The program 140 may be stored as software in the memory 130 and may include, for example, an operating system (OS) 142, middleware 144, or an application 146.

The input module 150 may receive, from the outside (e.g., a user) of the electronic device 101, a command or data to be used by another component (e.g., the processor 120) of the electronic device 101. The input module 150 may include, for example, a microphone, a mouse, a keyboard, a key (e.g., a button), or a digital pen (e.g., a stylus pen).

The sound output module 155 may output a sound signal to the outside of the electronic device 101. The sound output module 155 may include, for example, a speaker or a receiver. The speaker may be used for general purposes, such as playing multimedia or playing a recording. The receiver may be used to receive an incoming call. According to an embodiment, the receiver may be implemented separately from the speaker or as a part of the speaker.

The display module 160 may visually provide information to the outside (e.g., a user) of the electronic device 101. The display module 160 may include, for example, a display, a hologram device, or a projector and a control circuit to control a corresponding one of the display, the hologram device, and the projector. According to an embodiment, the display module 160 may include a touch sensor adapted to detect a touch or a pressure sensor adapted to measure an intensity of a force incurred by the touch.

The audio module 170 may convert a sound into an electric signal or vice versa. According to an embodiment, the audio module 170 may obtain the sound via the input module 150 or output the sound via the sound output module 155 or an external electronic device (e.g., an electronic device 102, such as a speaker or headphones) directly or wirelessly connected to the electronic device 101.

The sensor module 176 may detect an operational state (e.g., power or temperature) of the electronic device 101 or an environmental state (e.g., a state of a user) external to the electronic device 101 and generate an electric signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., by wire) or wirelessly. According to an embodiment, the interface 177 may include, for example, a high-definition multimedia interface (HDMI), a universal serial bus (USB) interface, a secure digital (SD) card interface, or an audio interface.

The connecting terminal 178 may include a connector via which the electronic device 101 may be physically connected to an external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electric signal into a mechanical stimulus (e.g., a vibration or a movement) or an electrical stimulus, which may be recognized by a user via his or her tactile sensation or kinesthetic sensation. According to an embodiment, the haptic module 179 may include, for example, a motor, a piezoelectric element, or an electric stimulator.

The camera module 180 may capture a still image and moving images. According to an embodiment, the camera module 180 may include one or more lenses, image sensors, ISPs, or flashes.

The power management module 188 may manage power supplied to the electronic device 101. According to an embodiment, the power management module 188 may be implemented as, for example, at least a part of a power management integrated circuit (PMIC).

The battery 189 may supply power to at least one component of the electronic device 101. According to an embodiment, the battery 189 may include, for example, a primary cell, which is not rechargeable, a secondary cell, which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently from the processor 120 (e.g., an AP) and that support direct (e.g., wired) communication or wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module, or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., a LAN or a wide area network (WAN))). These various types of communication modules may be implemented as a single component (e.g., a single chip), or may be implemented as multiple components (e.g., multiple chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a fourth-generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in a communication network, such as the first network 198 or the second network 199, may be selected by, for example, the communication module 190 from the plurality of antennas. The signal or the power may be transmitted or received between the communication module 190 and the external electronic device via the selected at least one antenna. According to an embodiment, another component (e.g., a radio frequency integrated circuit (RFIC)) other than the radiating element may be additionally formed as a part of the antenna module 197.

According to various embodiments, the antenna module 197 may form a mmWave antenna module. According to an embodiment, the mm Wave antenna module may include a PCB, an RFIC disposed on a first surface (e.g., the bottom surface) of the PCB or adjacent to the first surface and capable of supporting a designated high-frequency band (e.g., the mmWave band), and a plurality of antennas (e.g., array antennas) disposed on a second surface (e.g., the top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 and 104 may be a device of a same type as, or a different type from, the electronic device 101. According to an embodiment, all or some of operations to be executed by the electronic device 101 may be executed at one or more external electronic devices (e.g., the external electronic devices 102 and 104, and the server 108). For example, if the electronic device 101 needs to perform a function or a service automatically, or in response to a request from a user or another device, the electronic device 101, instead of, or in addition to, executing the function or the service, may request one or more external electronic devices to perform at least part of the function or the service. The one or more external electronic devices receiving the request may perform the at least part of the function or the service requested, or an additional function or an additional service related to the request, and may transfer a result of the performance to the electronic device 101. The electronic device 101 may provide the result, with or without further processing the result, as at least part of a response to the request. To that end, cloud computing, distributed computing, mobile edge computing (MEC), or client-server computing technology may be used, for example. The electronic device 101 may provide ultra low-latency services using, e.g., distributed computing or MEC. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., a smart home, a smart city, a smart car, or healthcare) based on 5G communication technology or IoT-related technology.

According to an embodiment, each of the external electronic devices 102 and 104 may be a device of the same type as or a different type from the electronic device 101. According to an embodiment, all or some of operations to be executed by the electronic device 101 may be executed at one or more external electronic devices (e.g., the external electronic devices 102 and 104, and the server 108). For example, if the electronic device 101 needs to perform a function or a service automatically, or in response to a request from a user or another device, the electronic device 101, instead of, or in addition to, executing the function or the service, may request one or more external electronic devices to perform at least part of the function or the service. The one or more external electronic devices receiving the request may perform the at least part of the function or the service requested, or an additional function or an additional service related to the request, and may transfer an outcome of the performing to the electronic device 101. The electronic device 101 may provide the result, with or without further processing the result, as at least part of a response to the request.

For example, after rendering content data executed by an application, the external electronic device 102 may transmit the content data to the electronic device 101 and the electronic device 101 receiving the data may output the content data to the display module 160. When the electronic device 101 detects a motion of a user through a sensor, the processor of the electronic device 101 may correct the rendered data received from the external electronic device 102 based on information on the motion and output the corrected data to the display module. Alternatively, the processor 120 of the electronic device 101 may transmit movement information to the external electronic device 102 and request rendering so that screen data is updated accordingly. According to an embodiment, the external electronic device 102 may be a device in various forms, such as a smartphone or a case device for storing and charging the electronic device 101.

The electronic device according to the embodiments disclosed herein may be one of various types of electronic devices. The electronic device may include, for example, a portable communication device (e.g., a smartphone), a computer device, a portable multimedia device, a portable medical device, a camera, a wearable device, or a home appliance device. According to an embodiment of the disclosure, the electronic device is not limited to those described above.

It should be appreciated that the embodiments of the disclosure and the terms used therein are not intended to limit the technological features set forth herein to particular embodiments and include various changes, equivalents, or replacements for a corresponding embodiment. As used herein, “A or B,” “at least one of A and B,” “at least one of A or B,” “A, B or C,” “at least one of A, B and C,” and “at least one of A, B, or C,” may include any one of the items listed together in the corresponding one of the phrases, or all possible combinations thereof. Terms such as “1st” and “2nd,” or “first” and “second” may be used to simply distinguish a corresponding component from other components, and do not limit the components in other aspects (e.g., importance or order). It is to be understood that if a component (e.g., a first component) is referred to, with or without the term “operatively” or “communicatively”, as “coupled with,” “coupled to,” “connected with,” or “connected to” another component (e.g., a second component), the component may be coupled with the other component directly (e.g., by wire), wirelessly, or via a third component.

As used in connection with embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to embodiments disclosed herein may be included and provided in a computer program product. The computer program product may be traded as a product between a seller and a buyer. The computer program product may be distributed in the form of a machine-readable storage medium (e.g., a compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to embodiments, each component (e.g., a module or a program) of the above-described components may include a single entity or multiple entities, and some of the multiple entities may be separately disposed in different components. According to various embodiments, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more of other operations may be added.

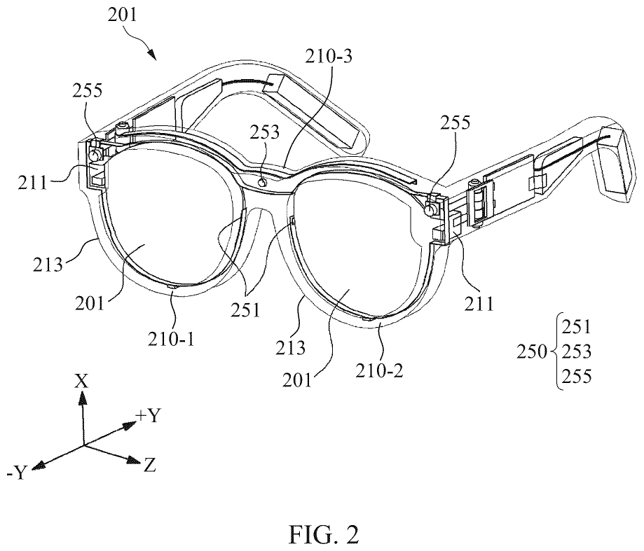

FIG. 2 is a perspective view illustrating an internal configuration of a wearable electronic device according to an embodiment of the disclosure.

Referring to FIG. 2, a wearable electronic device 201 according to an embodiment may include at least one of a light output module 211, a display member 213, and a camera module 250. An electronic device (e.g., the electronic device 101 of FIG. 1) may be implemented in the form of the wearable electronic device 201.

In an embodiment, the wearable electronic device 201 may include a pair of frames 210-1 and 210-2 on which a pair of lenses are respectively mounted and a bridge 210-3 connecting the pair of frames 210-1 and 210-2. A temple to be worn by a user may be provided to the end of each frame of each frames (210-1, 210-2).

According to an embodiment, the light output module 211 may include a light source to output an image and a lens to guide an image to the display member 213. According to an embodiment, the light output module 211 may include at least one of a liquid crystal display (LCD), a digital micromirror display device (DMD), a liquid crystal on silicon (LCoS), an organic light-emitting diode (OLED), or a micro light-emitting diode (micro LED).

According to an embodiment, the display member 213 may include an optical waveguide (e.g., a waveguide). According to an embodiment, an image output by the light output module 211, incident on one end of the optical waveguide, may propagate inside the optical waveguide and be provided to the user. According to an embodiment, the optical waveguide may include at least one of diffraction elements (e.g., a diffractive optical element (DOE) and a holographic optical element (HOE)) or at least one of reflective elements (e.g., a reflection mirror). For example, the optical waveguide may guide the image output by the light output module 211 to the eyes of the user using the at least one diffractive element or the reflective element.

According to an embodiment, the camera module 250 may capture a still image and/or a moving image. According to an embodiment, the camera module 250 may be disposed within a lens frame and disposed around the display member 213.

According to an embodiment, a first camera module 251 may capture and/or recognize a trajectory of a gaze or eye (e.g., the pupil or the iris) of the user. According to an embodiment, the first camera module 251 may periodically or aperiodically transmit information (e.g., trajectory information) associated with the trajectory of the gaze or eye of the user to a processor (e.g., the processor 120 of FIG. 1).

According to an embodiment, a second camera module 253 may capture an external image.

According to an embodiment, a third camera module 255 may be used for hand detection and tracking and for recognition of a gesture (e.g., a hand gesture) of the user. The third camera module 255 according to an embodiment may be used for three degrees of freedom (3DoF) and six degrees of freedom (6DoF) head tracking, recognition of a position (space and environment), and/or recognition of a movement. The second camera module 253 may also be used for hand detection and tracking and for recognition of a gesture of the user. According to an embodiment, at least one of the first camera module 251 to the third camera module 255 may be replaced by a sensor module (e.g., a light detection and ranging (LiDAR) sensor). For example, the sensor module may include at least one of a vertical-cavity surface-emitting laser (VCSEL), an infrared sensor, and/or a photodiode.

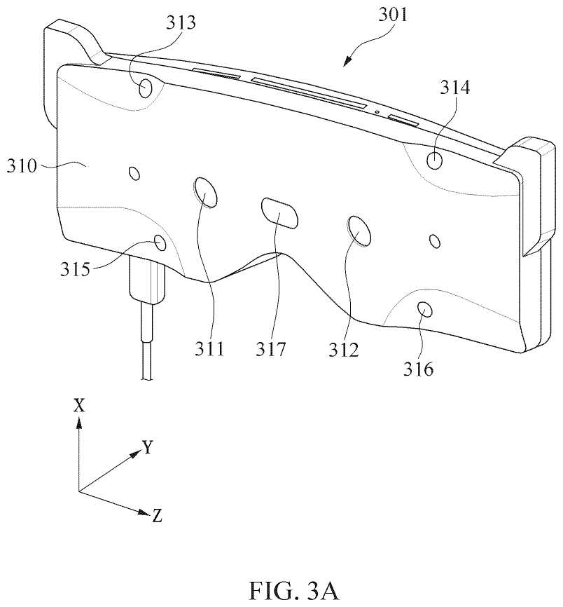

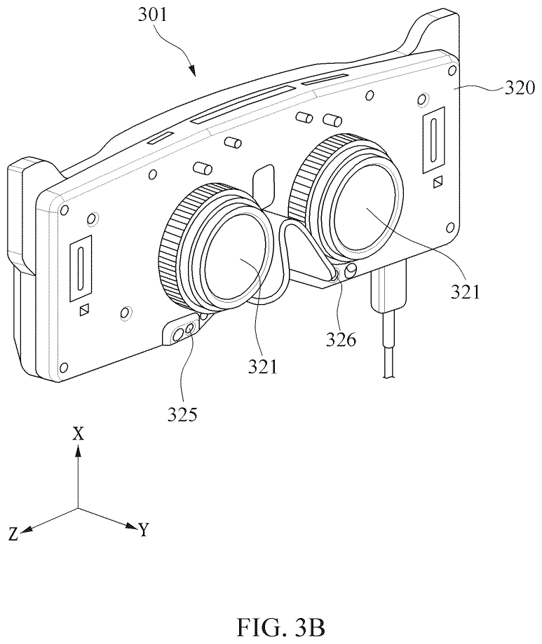

FIG. 3A is a diagram illustrating a front surface of a wearable electronic device according to an embodiment of the disclosure.

FIG. 3B is a diagram illustrating a rear surface of the wearable electronic device according to an embodiment of the disclosure.

Referring to FIGS. 3A and 3B, an electronic device (e.g., the electronic device 101 of FIG. 1) may be implemented in the form of a wearable electronic device 301 (e.g., the wearable electronic device 201 of FIG. 2). Camera modules 311, 312, 313, 314, 315, and 316 and/or a depth sensor 317 for obtaining information related to the surrounding environment of the wearable electronic device 301 may be disposed on a first surface 310 of a housing.

In an embodiment, the camera modules 311 and 312 may obtain an image related to the surrounding environment of the wearable electronic device 301.

In an embodiment, the camera modules 313, 314, 315, and 316 may obtain an image in a state in which the wearable electronic device is worn by a user. The camera modules 313, 314, 315, and 316 may be used for hand detection and tracking and for recognition of a gesture (e.g., a hand gesture) of the user. The camera modules 313, 314, 315, and 316 may be used for 3DoF and 6DoF head tracking, recognition of a position (space and environment), and/or recognition of a movement. In an embodiment, the camera modules 311 and 312 may be used for hand detection and tracking and for recognition of a gesture of the user.

In an embodiment, the depth sensor 317 may be configured to transmit a signal and receive a signal reflected from an object and may be used to determine a distance from an object based on a time of flight (TOF). Instead of or in addition to the depth sensor 317, the camera modules 313, 314, 315, and 316 may determine a distance from an object.

In an embodiment, camera modules 325 and 326 for face recognition and/or a display 321 (and/or a lens) may be disposed on a second surface 320 of the housing.

In an embodiment, the camera modules 325 and 326 for face recognition adjacent to a display may be used to recognize the face of the user or may recognize and/or track both eyes of the user.

In an embodiment, the display 321 (and/or a lens) may be disposed on the second surface 320 of the wearable electronic device 301. In an embodiment, the wearable electronic device 301 may not include the camera modules 315 and 316 among the plurality of camera modules 313, 314, 315, and 316. Although not shown in FIGS. 3A and 3B, the wearable electronic device 301 may further include at least one components among the components shown in FIG. 2.

As described above, the wearable electronic device 301 according to an embodiment may have a form factor to be worn on the head of the user. The wearable electronic device 301 may further include a wearing member and/or a strap to be fixed onto a body part of the user. When worn on the head of the user, the wearable electronic device 301 may provide a user experience based on augmented reality (AR), virtual reality (VR), and/or mixed reality (MR).

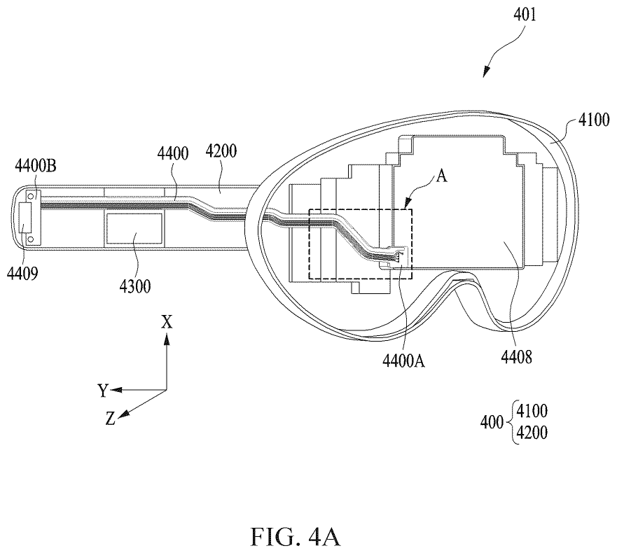

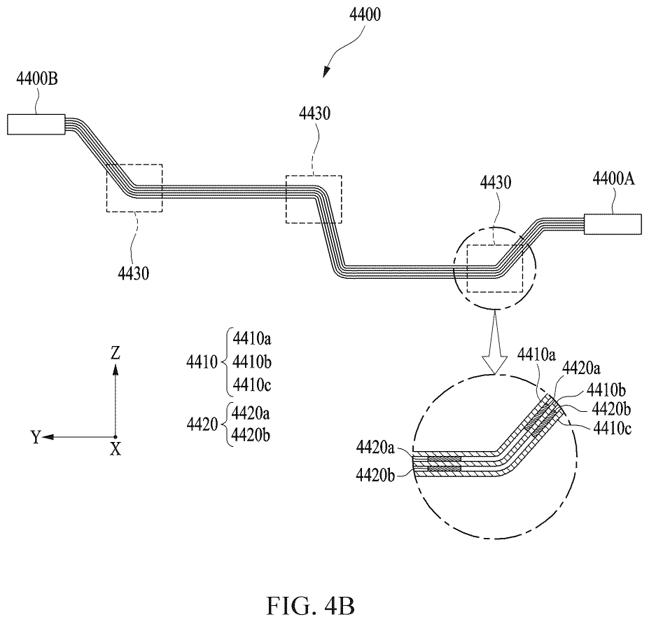

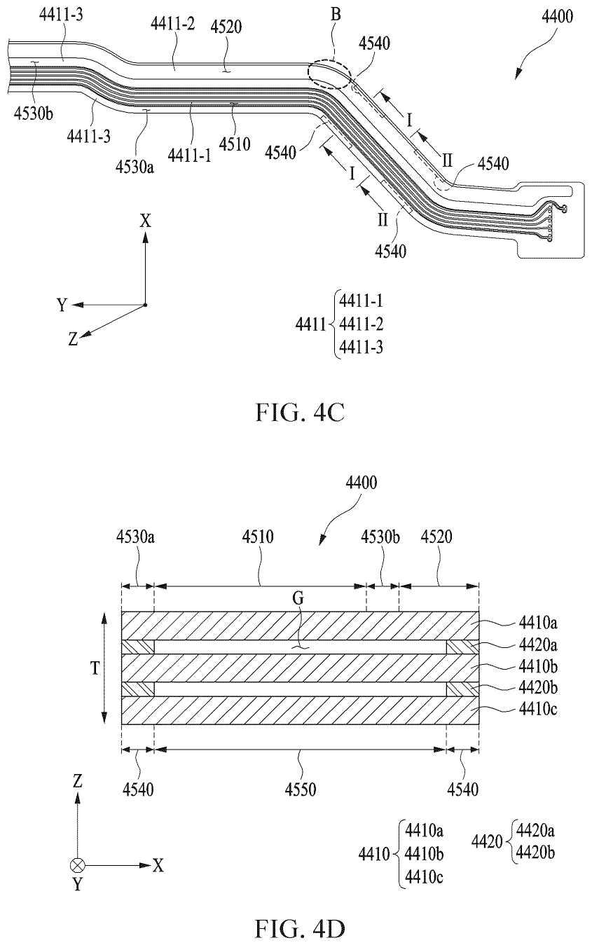

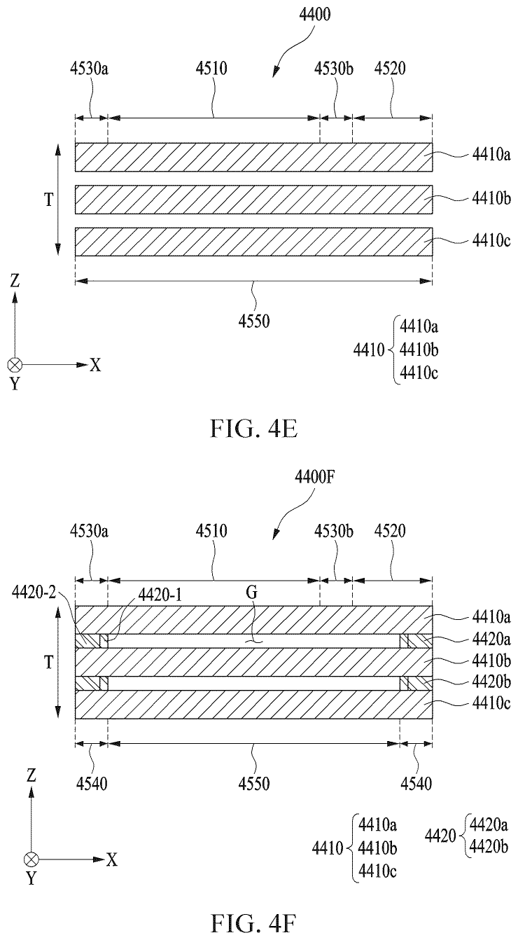

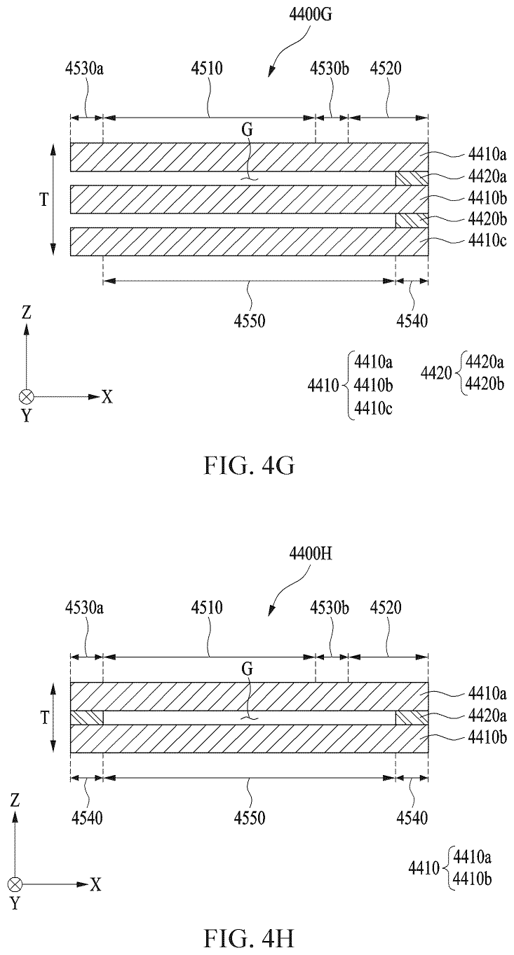

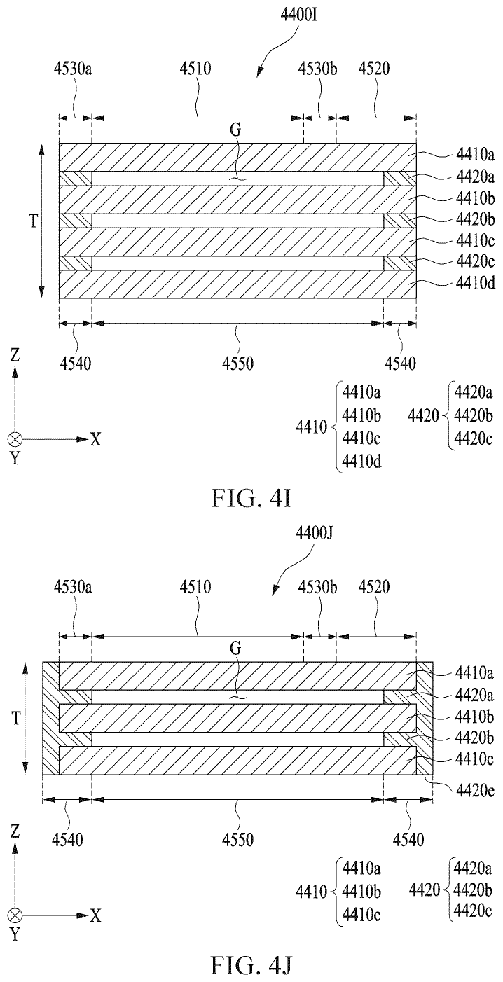

FIG. 4A is a see-through perspective view of a wearable electronic device according to an embodiment of the disclosure.

FIG. 4B is a side view of a flexible printed circuit board (FPCB) according to an embodiment of the disclosure.

FIG. 4C is a partially enlarged view of an area A of the FPCB of FIG. 4A according to an embodiment of the disclosure.

FIG. 4D is a cross-sectional view of the FPCB taken along the line I-I of FIG. 4C according to an embodiment of the disclosure.

FIG. 4E is a cross-sectional view of the FPCB taken along the line II-II of FIG. 4C according to an embodiment of the disclosure.

FIG. 4F is a cross-sectional view of the FPCB taken along the line I-I of FIG. 4C according to an embodiment of the disclosure. FIG. 4G is a cross-sectional view of the FPCB taken along the line I-I of FIG. 4C according to an embodiment of the disclosure.

FIG. 4H is a cross-sectional view of the FPCB taken along the line I-I of FIG. 4C according to an embodiment of the disclosure.

FIG. 4I is a cross-sectional view of the FPCB taken along the line I-I of FIG. 4C according to an embodiment of the disclosure.

FIG. 4J is a cross-sectional view of the FPCB taken along the line I-I of FIG. 4C according to an embodiment of the disclosure.

Referring to FIG. 4A, a wearable electronic device 401 according to an embodiment (e.g., the electronic device 101 of FIG. 1, the wearable electronic device 201 of FIG. 2, and the wearable electronic device 301 of FIG. 3A) may include a housing 400 forming the exterior of the wearable electronic device 401 and an FPCB 4400 disposed in the housing 400.

In an embodiment, the housing 400 may include a frame 4100 and a temple 4200. In an embodiment, the frame 4100 may be positioned on the face of a user while the wearable electronic device 401 is worn on the head of the user. The frame 4100 may be mounted on the head of the user, for example, to cover the eyes of the user. In an embodiment, the frame 4100 may have at least one lens or at least one display (e.g., the display 321 of FIG. 3B) disposed on a part corresponding to the eyes of the user.

The temple 4200 may extend from each end (e.g., in the +/−Z direction) of the frame 4100. In an embodiment, the temple 4200 may be mounted on a side surface of the head of the user while the wearable electronic device 401 is worn on the head of the user. For example, the temple 4200 may be mounted to fit over the ear of the user and support the wearable electronic device 401 to be secured to the head of the user. In an embodiment, the temple 4200 may be formed as a pair, one at each end of the frame 4100. In another example, the temple 4200 may be formed as a single member that is connected to both ends of the frame 4100 and wraps around the head of the user. For example, the temple 4200 may be formed of a flexible material and formed to wrap around the head of the user. In an embodiment, the temple 4200 may be formed to be foldable or partially bendable relative to the frame 4100. As the connection form of the temple 4200 to the frame 4100 changes, the form of the wearable electronic device 401 may change during its use.

At least one electronic component may be disposed in the housing 400. For example, the wearable electronic device 401 may include a PCB 4408 disposed in the frame 4100 and having at least one component element mounted thereon. A processor (e.g., the processor 120 of FIG. 1) for controlling the operation of the wearable electronic device 401 may be disposed on the PCB 4408, for example. The wearable electronic device 401 may include a speaker 4300, a microphone, a battery, an antenna, and/or various types of sensors disposed in the housing 400.

In an embodiment, the wearable electronic device 401 may include at least one connecting terminal 4409 to be connected to an external electronic device and/or an external power source. In an embodiment, the connecting terminal 4409 may have a connector shape. In an embodiment, the connecting terminal 4409 may be disposed at an extended end of the temple 4200, but the location of the connecting terminal 4409 is not limited thereto.

In an embodiment, the FPCB 4400 may electrically connect two or more component elements in the wearable electronic device 401. For example, the FPCB 4400 may be disposed to cross the frame 4100 and the temple 4200 of the wearable electronic device 401, a first end 4400A may be connected to the PCB 4408 disposed on the frame 4100, and a second end 4400B may be connected to the connecting terminal 4409 disposed on the temple 4200. The FPCB 4400 may electrically connect two interconnected component elements, for example, the PCB 4408 and the connecting terminal 4409 and may transmit a data signal and/or a power signal between the PCB 4408 and the connecting terminal 4409. The arrangement position and shape of the FPCB 4400 disposed in the wearable electronic device 401 illustrated in the diagram are an example, and the arrangement position and shape of the FPCB 4400 may be changed in various ways. For example, in the structure of the wearable electronic device (the wearable electronic device 201 of FIG. 2) illustrated in FIG. 2, at least a portion of the FPCB may bend and be disposed in the bridge 210-3 connecting the pair of lens frames 210-1 and 210-2.

In an embodiment, the FPCB 4400 may be formed to be flexible so as to be partially bendable. The FPCB 4400 may be disposed in a partially bent state in the housing 400. For example, as illustrated in FIG. 4A, when the FPCB 4400 is disposed on the temple 4200 so that a portion of the FPCB 4400 overlaps the speaker 4300, the part of the FPCB 4400 overlapping the speaker 4300 may partially bend in accordance with the thickness of the speaker 4300. In an embodiment, the FPCB 4400 may be configured to be partially bendable in response to the shape of the wearable electronic device 401 or a change in a form factor depending on use.

Referring to FIGS. 4B, 4C, 4D, and 4E, in an embodiment, the FPCB 4400 may include a plurality of substrate layers 4410 disposed to overlap on another in a thickness direction (e.g., in the Z-axis direction) of the FPCB 4400 and at least one connecting layer 4420 that partially connects the plurality of substrate layers 4410 in the thickness direction (e.g., in the Z-axis direction) of the FPCB 4000. In an embodiment, the FPCB 4400 may include at least one bending portion 4430 that partially bends in the thickness direction (e.g., the Z-axis direction) of the FPCB 4400. For example, as illustrated in FIG. 4A, when the FPCB 4400 is disposed to cross the frame 4100 and the temple 4200 of the wearable electronic device 401, the bending portion 4430 of the FPCB 4400 may be formed at a part in which the frame 4100 is connected to the temple 4200.

In an embodiment, the plurality of substrate layers 4410 may extend in the longitudinal direction of the FPCB 4400. The plurality of substrate layers 4410 may be formed with substantially the same area and may be sequentially stacked in the thickness direction of the FPCB. For example, the plurality of substrate layers 4410 may include a first substrate layer 4410a, a second substrate layer 4410b, and a third substrate layer 4410c that are sequentially disposed to overlap one another in the −Z direction. In an embodiment, each of the plurality of substrate layers 4410 may be formed of a flexible material, for example, a polyimide (PI) material. A metal pattern for forming a circuit line may be formed on a surface of each substrate layer. The metal pattern may be formed of, for example, a copper (Cu) material.

In an embodiment, at least one connecting layer 4420 may be disposed on at least a portion between the plurality of substrate layers 4410 to connect adjacent substrate layers 4410 to each other. For example, the connecting layer 4420 may bond adjacent substrate layers 4410 in the thickness direction. In an embodiment, when the FPCB 4400 includes three substrate layers (the first substrate layer 4410a, the second substrate layer 4410b, and the third substrate layer 4410c), the connecting layer 4420 may include at least one first connecting layer 4420a disposed between the first substrate layer 4410a and the second substrate layer 4410b and at least one second connecting layer 4420b disposed between the second substrate layer 4410b and the third substrate layer 4410c. In an embodiment, each connecting layer 4420 may bond a pair of substrate layer 4410 parts with each other that are in contact with both surfaces of the connecting layer 4420. For example, the connecting layer 4420 may be formed of a prepreg (PP) material or a bonding sheet that performs a bonding function. In an embodiment, each connecting layer 4420 may be formed of only one of a PP material and a bonding sheet but may also be formed by mixing the PP material and the bonding sheet. However, this is only an example, and the material of the connecting layer 4420 is not limited thereto.

In an embodiment, a plurality of first connecting layers 4420a may be disposed at different positions between the first substrate layer 4410a and the second substrate layer 4410b, and the first substrate layer 4410a and the second substrate layer 4410b may be mutually bonded to each other in a region overlapping the plurality of first connecting layers 4420a (e.g., an area overlapping in the Z-axis direction). A plurality of second connecting layers 4420b may be disposed at different positions between the second substrate layer 4410b and the third substrate layer 4410c, and the second substrate layer 4410b and the third substrate layer 4410c may be bonded with each other in a region (e.g., a region overlapping in the Z-axis direction) overlapping the plurality of second connecting layers 4420b.

In an embodiment, a plurality of connecting layers 4420 may bond the plurality of substrate layers 4410 with each other in the thickness direction with the bending portion 4430 of the FPCB 4400 therebetween. Accordingly, the FPCB 4400 may have at least some of the substrate layers 4410 bonded with one another at a part adjacent to the bending portion 4430 so that the phenomenon of a gap between each substrate layer 4410 at the bending portion 4430 may be reduced or prevented.

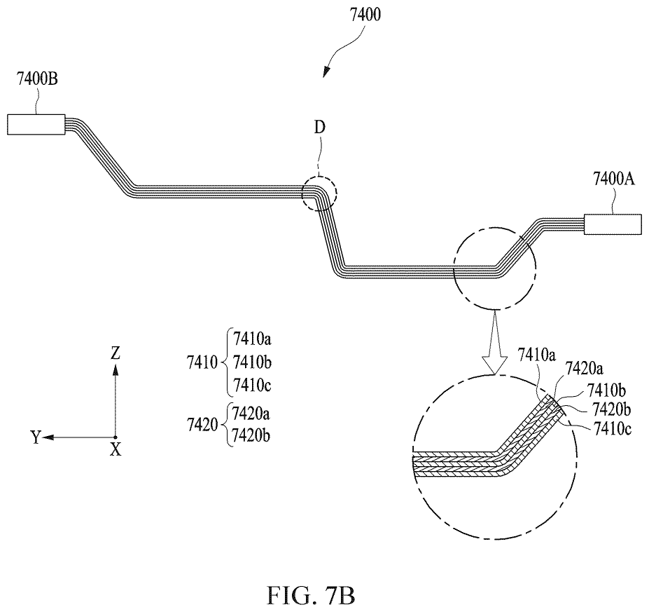

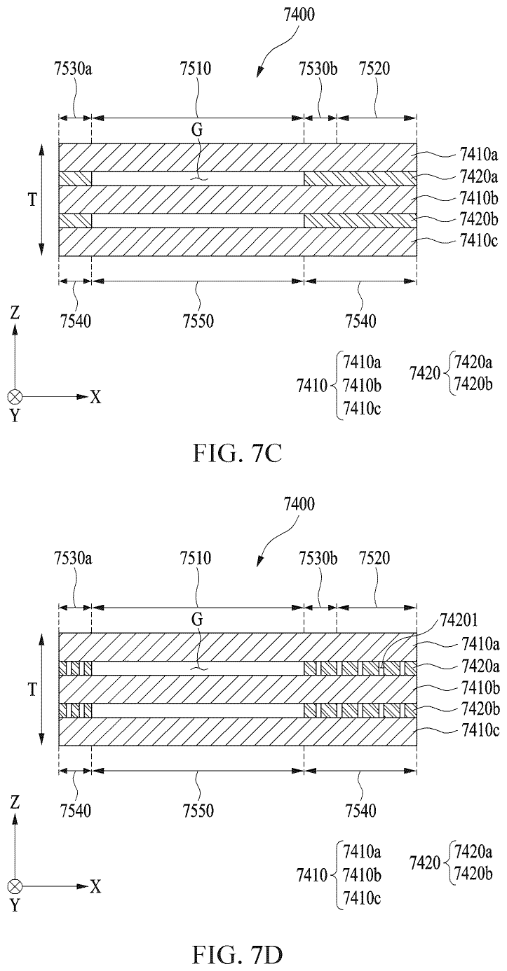

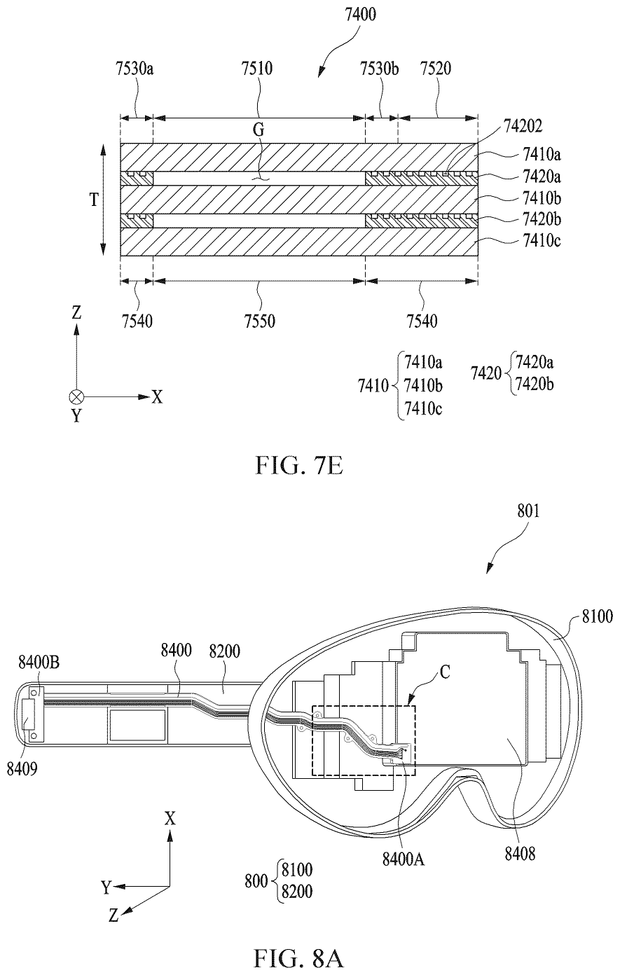

In an embodiment, a plurality of through holes (e.g., a slit 74201 of FIG. 7C) or a plurality of recesses (e.g., a recess 740202 of FIG. 7D) may be formed in each connecting layer 4420. For example, a through hole, a slit, or a plurality of recesses formed in the connecting layer 4420 may form a gap between parts of the substrate layer 4410 that overlap the connecting layer 4420.

Hereinafter, a description is provided mainly based on an embodiment in which the FPCB 4400 includes three substrate layers 4410 and the plurality of connecting layers 4420 disposed between the substrate layers 4410. However, this is only an example for ease of description, and the number of layers of the FPCB 4400 is not limited thereto. For example, as illustrated in FIG. 4H, an FPCB 4400F may be formed with a structure in which two substrate layers 4410 overlap each other, and as illustrated in FIG. 4I, an FPCB 4400G may be formed with a structure in which four or more substrate layers 4410 overlap one another.

In an embodiment, as illustrated in FIG. 4C, at least one circuit line 4411 may be formed on the surface of each of the substrate layers 4410. Based on one substrate layer 4410, the circuit line 4411 may be formed on both surfaces or only one surface of the substrate layer 4410. In an embodiment, the circuit line 4411 formed on the substrate layer 4410 may include a data line 4411-1 for transmitting a data signal, a power line 4411-2 for transmitting a power signal, and a ground line 4411-3 for grounding. In an embodiment, each of the data line 4411-1, the power line 4411-2, and the ground line 4411-3 may be formed in the substrate layer 4410 so as to extend in the longitudinal direction of the FPCB 4400.

In an embodiment, the circuit line 4411 formed on each of the plurality of substrate layers 4410 may be formed in a different shape and number. In an embodiment, the data lines 4411-1 formed on the respective surfaces of the substrate layers 4410 may be formed at positions that overlap each other in the thickness direction of the FPCB 4400. Power lines 4411-2 formed on the respective surfaces of the substrate layers 4410 may be formed at positions that overlap each other in the thickness direction of the FPCB 4400. Ground lines 4411-3 formed on the respective surfaces of the substrate layers 4410 may be formed at positions that overlap each other in the thickness direction of the FPCB 4400. Hereinafter, for ease of description, an embodiment in which the data lines 4411-1, the power lines 4411-2, and the ground lines 4411-3 formed on the plurality of substrate layers 4410 of the FPCB 4400 overlap each other in the thickness direction of FPCB 4400 is described. However, this is only an example, and the arrangement of a circuit line formed on each of the substrate layers 4410 is not limited thereto.

In an embodiment, when the FPCB 4400 is viewed in a thickness direction T (e.g., Z-axis), for example, when a surface of the FPCB 4400 (e.g., the first substrate layer 4410a) is viewed, the FPCB 4400 may include a first circuit region 4510 in which the data line 4411-1 is positioned, a second circuit region 4520 in which the power line 4411-2 is positioned, and a third circuit region 4530a or 4530b in which the ground line 4411-3 is positioned. In an embodiment, the first circuit region 4510, the second circuit region 4520, and the third circuit region 4530 may not overlap each other when the FPCB 4400 is viewed in the thickness direction T. In an embodiment, the third circuit region 4530a or 4530b may be formed integrally or may include a plurality of separate regions. For example, the third circuit region 4530a or 4530b may include a (3-1)-th circuit region 4530a and a (3-2)-th circuit region 4530b positioned on both sides in the width direction (e.g., X-axis direction) of the first circuit region 4510 in which the data line 4411-1 is formed.

In an embodiment, when viewed in the thickness direction T, the FPCB 4400 may be divided into at least one connecting region 4540 in which at least one pair of substrate layers 4410 are bonded with each other by the connecting layer 4420 and a non-connecting region 4550 in which the substrate layers 4410 are not bonded with one another. For example, it may be understood that the connecting layer 4420 is positioned in a part of the FPCB 4400 corresponding to the connecting region 4540. In an embodiment, a plurality of connecting regions 4540 may be formed on the FPCB 4400. The plurality of connecting regions 4540 may be formed in different parts of the FPCB 4400. In an embodiment, the connecting region 4540 in the FPCB 4400 may be formed in a part that does not overlap the first circuit region 4510. For example, the connecting layer 4420 may be omitted from the surface of the substrate layer 4410 on which the data line 4411-1 is formed, and the first circuit region 4510 of the FPCB 4400 may be formed as the non-connecting region 4550.

In an embodiment, the connecting region 4540 may be formed in a part overlapping the second circuit region 4520 and/or the third circuit region 4530. For example, the connecting layer 4420 may be disposed on a surface part of the substrate layer 4410 in which the power line 4411-2 is formed or may be disposed on a surface part of the substrate layer 4410 in which the ground line 4411-3 is formed. In this case, at least a portion of the second circuit region 4520 of the FPCB 4400 may be formed as the connecting region 4540, and the remaining portion of the second circuit region 4520 may be formed as the non-connecting region 4550. At least a portion of the third circuit region 4530 of the FPCB 4400 may be formed as the connecting region 4540, and the remaining portion of the third circuit region 4530 may be formed as the non-connecting region 4550.

In an embodiment, when the connecting region 4540 in the FPCB 4400 is formed at a position that does not overlap the first circuit region 4510, a part in which the data line 4411-1 of each substrate layer 4410 is formed may be spaced apart from another substrate layer 4410. In this case, the phenomenon in which signals transmitted through the data line 4411-1 disposed in the first circuit region 4510 of adjacent substrate layers 4410 may interfere with each other and the data transmission performance of the FPCB 4400 deteriorates may be reduced or prevented.

In an embodiment, the connecting region 4540 of the FPCB 4400 may be formed at an edge in the width direction (e.g., the X-axis direction of FIG. 4D) of the FPCB 4400. For example, based on a cross-section of a part of the FPCB 4400 in which the connecting region 4540 is positioned, as illustrated in FIG. 4D, a pair of connecting regions 4540 may be formed respectively at ends in the width direction of the FPCB 4400. In the connecting region 4540, the first connecting layer 4420a may be disposed between the first substrate layer 4410a and the second substrate layer 4410b, and the second connecting layer 4420b may be disposed between the second substrate layer 4410b and the third substrate layer 4410c. Void spaces G may be formed between the substrate layers 4410a, 4410b, and 4410c in the non-connecting region 4550.

Referring to FIG. 4D, the connecting region 4540 may be formed not to overlap the first circuit region 4510 of the FPCB 4400 in the thickness direction T. For example, the connecting region 4540 positioned at the −X-axis end of the FPCB 4400 may be formed to overlap the (3-1)-th circuit region 4530a of the FPCB 4400 in the thickness direction T, and the substrate layers 4410a, 4410b, and 4410c in the (3-1)-th circuit region 4530a may be connected to one another through the connecting layers 4420a and 4420b disposed therebetween. The connecting region 4540 positioned at the +X-axis end of the FPCB 4400 may be formed to overlap the second circuit region 4520 of the FPCB 4400, and in a portion of the second circuit region 4520, the substrate layers 4410a, 4410b, and 4410c may be connected to one another through the connecting layers 4420a and 4420b disposed therebetween. In the example illustrated in FIG. 4D, the first connecting layer 4420a and the second connecting layer 4420b disposed in the connecting region are illustrated as having the same thickness and width. However, this is only an example, and the first connecting layer 4420a and the second connecting layer 4420b may have different thicknesses and/or widths at positions that do not overlap the first circuit region 4510. The non-connecting region 4550 may be formed between the pair of connecting regions 4540 positioned at the end in the width direction of the FPCB 4400, and void spaces G may be formed between the substrate layers 4410 of the FPCB 4400 in the non-connecting region 4550.

As illustrated in FIG. 4E, a part of the FPCB 4400 in which the connecting region 4540 is not formed in the width direction is formed only as the non-connecting region 4550, so the substrate layers 4410a, 4410b, and 4410c may separately overlap one another in the thickness direction T.

In an embodiment, the FPCB 4400 may maintain the flexible performance of the FPCB 4400 by preventing excessive gaps between the plurality of substrate layers 4410 by bonding only a portion of the plurality of substrate layers 4410 through the connecting region 4540 in which the connecting layer 4420 is disposed, while enabling individual bending of each of the substrate layers 4410a, 4410b, and 4410c through the non-connecting region 4550 in which the connecting layer 4420 is omitted.

In an embodiment, when a plurality of connecting layers 4420 is disposed on the FPCB 4400, at least some of the plurality of connecting layers 4420 may be formed of different materials. For example, the connecting layer 4420 may be formed of at least one of a PP sheet formed of a PP material and/or a bonding sheet formed of a bonding material, depending on the arrangement position of the connecting layer 4420 on the FPCB 4400. For example, as in the cross-section of FIG. 4D, when the pair of connecting regions 4540 is formed at both ends in the width direction (e.g., X-axis) of the first circuit region 4510, the connecting layer 4420 disposed to overlap the (3-1)-th circuit region 4530a that is relatively adjacent to the first circuit region 4510 may be formed of a bonding sheet, and the connecting layer 4420 disposed to overlap the second circuit region 4520 that is relatively spaced from the first circuit region 4510 may be formed of a PP sheet. Of course, the opposite is also possible.

In an embodiment, the plurality of connecting layers 4420 may be formed of different materials depending on the arrangement positions of the plurality of connecting layers 4420 on the FPCB 4400. For example, as the B region illustrated in FIG. 4C, when the connecting layer 4420 is disposed on a curved part of the FPCB 4400, the connecting layer 4420 may be formed of a bonding sheet, and when the connecting layer 4420 is disposed on a part of the FPCB 4400 in which the FPCB 4400 extends in a straight line, the connecting layer 4420 may be formed of a PP material. Of course, the opposite is also possible.

Referring to FIG. 4F, in the FPCB 4400F, at least one of the connecting layers 4420 disposed in one connecting region 4540 may be formed of a mixture of a plurality of materials. The plurality of connecting layers 4420 may be disposed on both ends of the FPCB 4400F in the width direction (e.g., X-axis) to overlap the (3-1)-th circuit region 4530a and the (3-2)-th circuit region 4530b. The connecting layer 4420 may include, for example, the first connecting layer 4420a disposed between the first substrate layer 4410a and the second substrate layer 4410b and the second connecting layer 4420b disposed between the second substrate layer 4410b and the third substrate layer 4410c. In an embodiment, at least one connecting layer 4420 may include a first connecting portion 4420-1 formed of a first material and a second connecting portion 4420-2 formed of a second material that is different from the first material. The first connecting portion 4420-1 may be disposed adjacent to the first circuit region 4510 compared to the second connecting portion 4420-2. The first material may include, for example, a bonding material, and the second material may include, for example, a PP material. Of course, the opposite is also possible. A void space G may be formed between the first substrate layer 4410a and the second substrate layer 4410b corresponding to the non-connecting region 4550.

Referring to FIG. 4G, in an embodiment, when the FPCB 4400G includes three substrate layers 4410 that are disposed to overlap one another in the thickness direction T, for example, the first substrate layer 4410a, the second substrate layer 4410b, and the third substrate layer 4410c, the first connecting layer 4420a may be disposed between the first substrate layer 4410a and the second substrate layer 4410b and the second connecting layer 4420b may be disposed between the second substrate layer 4410b and the third substrate layer 4410c. In an embodiment, the connecting layer 4420 may be disposed so as not to overlap the first circuit region 4510 in the thickness direction T. For example, as illustrated in FIG. 4G, the connecting layer 4420 may be disposed to overlap the second circuit region 4520 and/or the (3-2)-th circuit region 4530b positioned on the right side (e.g., in the +X direction) of the first circuit region 4510 to form the connecting region 4540. In another example, the connecting layer 4420 may be disposed to overlap the (3-1)-th circuit region 4530a positioned on the left side (e.g., in the −X direction) of the first circuit region 4510 to form the connecting region 4540. For example, the connecting region 4540 may be formed only on one of the left and right sides of the first circuit region 4510 based on the cross-section of the FPCB 4400G as illustrated in FIG. 4G. The non-connecting region 4550 may be formed in a part that does not overlap the connecting region 4540 in the thickness direction T.

Although not shown, in an embodiment, in the connecting region 4540 of the FPCB 4400G, at least one of the first connecting layer 4420a and the second connecting layer 4420b may be omitted. In another example, the first connecting layer 4420a and the second connecting layer 4420b may be formed of different materials or have different areas.

Referring to FIG. 4H, in an embodiment, when an FPCB 4400H includes two substrate layers 4410, for example, the first substrate layer 4410a and the second substrate layer 4410b, which are disposed to overlap each other in the thickness direction T, the first connecting layer 4420a may be disposed between the first substrate layer 4410a and the second substrate layer 4410b corresponding to the connecting region 4540. In an embodiment, as illustrated in FIG. 4H, when the pair of connecting regions 4540 is formed at both ends in the width direction of the FPCB 4400H, each connecting region 4540 may overlap the (3-1)-th circuit region 4530a and/or the second circuit region 4520 within a range that does not overlap the first circuit region 4510. The non-connecting region 4550 may be formed between a pair of connecting regions 4540, and the non-connecting region 4550 may overlap at least a portion except for the first circuit region 4510, the (3-2)-th circuit region 4530b, and/or the end in the +X direction of the second circuit region 4520. A void space G may be formed between the first substrate layer 4410a and the second substrate layer 4410b corresponding to the non-connecting region 4550.

Referring to FIG. 4I, in an embodiment, an FPCB 4400I may include the first substrate layer 4410a, the second substrate layer 4410b, the third substrate layer 4410c, and a fourth substrate layer 4410d that are sequentially disposed to overlap one another in the thickness direction T. In an embodiment, the first connecting layer 4420a, the second connecting layer 4420b, and a third connecting layer 4430b may be respectively disposed between the substrate layers 4410 corresponding to the connecting region 4540. In an embodiment, as illustrated in FIG. 4I, when the pair of connecting regions 4540 is formed at both ends in the width direction of the FPCB 4400F, each connecting region 4540 may overlap the (3-1)-th circuit region 4530a and/or the second circuit region 4520 within a range that does not overlap the first circuit region 4510. The non-connecting region 4550 may be formed between a pair of connecting regions 4540, and the non-connecting region 4550 may overlap at least a portion except for the first circuit region 4510, the (3-2)-th circuit region 4530b, and/or the end in the +X direction of the second circuit region 4520. Void spaces G may be formed between the first substrate layer 4410a, the second substrate layer 4410b, the third substrate layer 4410c, and the fourth substrate layer 4410d corresponding to the non-connecting region 4550.

Referring to FIG. 4J, in an embodiment, an FPCB 4400J may include a pair of connecting regions 4540 formed at both ends in the width direction. In an embodiment, the first connecting layer 4420a connecting the first substrate layer 4410a to the second substrate layer 4410b, the second connecting layer 4420b connecting the second substrate layer 4410b to the third substrate layer 4410c, and a side connecting layer 4420e formed to surround the first connecting layer 4420a, the second connecting layer 4420b, and a side surface (e.g., a side surface in the +/−X direction of the FPCB 4400H) of each substrate layer 4410 may be disposed in the connecting region 4540. In an embodiment, the side connecting layer 4420e may be formed by connecting the first connecting layer 4420a to the second connecting layer 4420b that protrude and extend to the side of the FPCB 4400H but may also be formed separately from the first connecting layer 4420a and the second connecting layer 4420b and bonded to the side of the FPCB 4400J.

In an embodiment, each connecting region 4540 may overlap the (3-1)-th circuit region 4530a and/or the second circuit region 4520 within a range that does not overlap the first circuit region 4510. The non-connecting region 4550 may be formed between a pair of connecting regions 4540, and the non-connecting region 4550 may overlap at least a portion except for the first circuit region 4510, the (3-2)-th circuit region 4530b, and/or the end in the +X direction of the second circuit region 4520. Void spaces G may be formed between the first substrate layer 4410a, the second substrate layer 4410b, and the third substrate layer 4410c corresponding to the non-connecting region 4550.

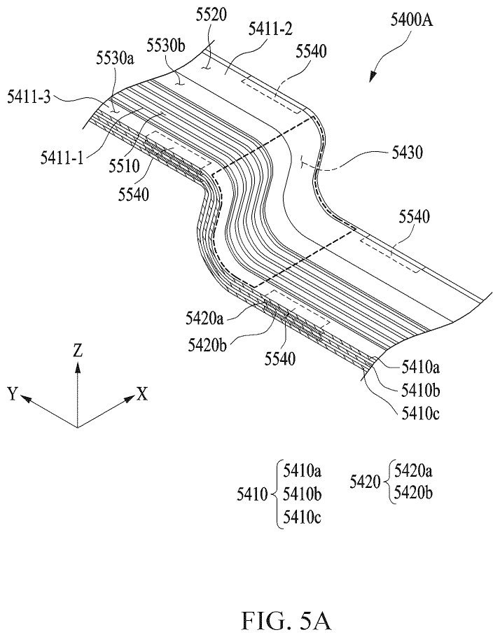

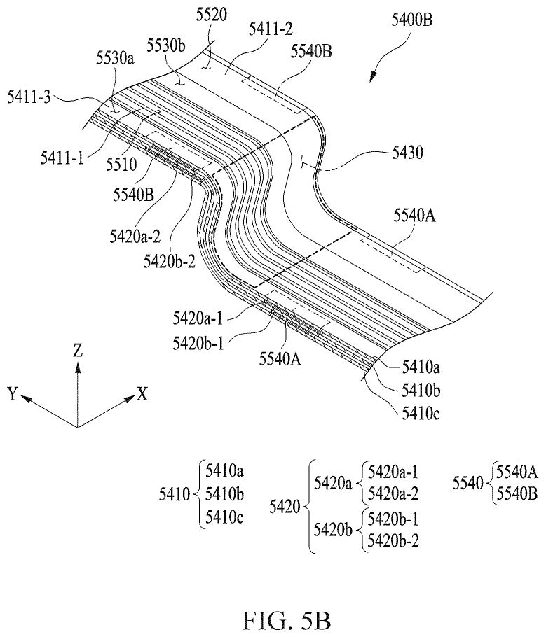

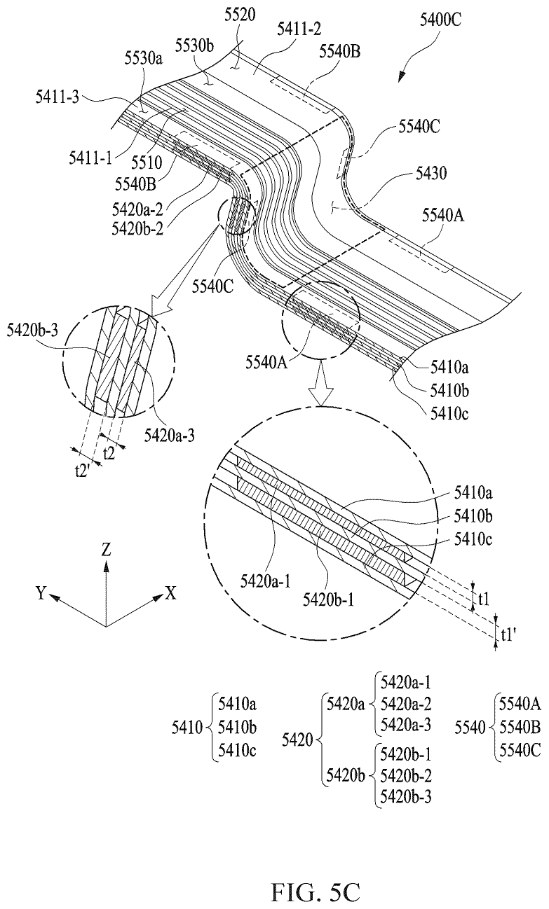

FIG. 5A is a partial perspective view illustrating a bending portion of an FPCB according to an embodiment of the disclosure.

FIG. 5B is a partial perspective view illustrating a bending portion of an FPCB according to an embodiment of the disclosure.

FIG. 5C is a partial perspective view illustrating a bending portion of an FPCB according to an embodiment of the disclosure.

Referring to FIGS. 5A to 5C, FPCBs 5400A, 5400B, and 5400C according to an embodiment may include a plurality of substrate layers 5410 that sequentially overlap one another in a thickness direction (e.g., in the Z-axis direction) and a plurality of connecting layers 5420 disposed between the plurality of substrate layers 5410 and bonding at least a portion between adjacent substrate layers 5410. For example, the plurality of substrate layers 5410 may include a first substrate layer 5410a, a second substrate layer 5410b, and a third substrate layer 5410c. For example, the plurality of connecting layers 5420 may include at least one first connecting layer 5420a disposed between the first substrate layer 5410a and the second substrate layer 5410b and a second connecting layer 5420b disposed between the second substrate layer 5410b and the third substrate layer 5410c.

In an embodiment, a data line 5411-1 for transmitting a data signal, a power line 5411-2 for transmitting a power signal, and a ground line 5411-3 for grounding may be formed on the surface of each substrate layer 5410. In an embodiment, when the FPCBs 5400A, 5400B, and 5400C are viewed in the thickness direction (e.g., Z-axis) of the FPCBs 5400A, 5400B, and 5400C, the FPCB 5400A may include a first circuit region 5510 in which the data line 5411-1 is positioned, a second circuit region 5520 in which the power line 5411-2 is positioned, and a third circuit region 5530a or 5530b in which the ground line 5411-3 is positioned. In an embodiment, the third circuit region 5530a or 5530b may include the (3-1)-th circuit region 5530a positioned to the left side in the width direction (e.g., −X direction) of the first circuit region 5510 and the (3-2)-th circuit region 5530b positioned to the right side in the width direction (e.g., the +X direction) of the first circuit region 5510. For example, the (3-2)-th circuit region 5530b may be positioned between the first circuit region 5510 and the second circuit region 5520.

In an embodiment, when viewing the surfaces of the FPCBs 5400A, 5400B, and 5400C, the FPCBs 5400A, 5400B, and 5400C may be divided into at least one connecting region 5540 in which at least one pair of substrate layers 5410 are connected to each other by the connecting layer 5420 and a non-connecting region 5550 in which the plurality of substrate layers 5410 is not connected to each other. For example, it may be understood that the connecting layer 5420 is disposed in a part of the FPCB 5400A corresponding to the connecting region 5540. In an embodiment, the connecting region 5540 may be formed in a part overlapping the first circuit region 5510 of the FPCBs 5400A, 5400B, and 5400C. For example, the connecting layer 5420 may be omitted from the surface of each substrate layer 5410 on which the data line 5411-1 is formed.

Referring to FIG. 5A, the FPCB 5400A may include a bending portion 5430 in which a plurality of substrate layers 5410 partially bends. In an embodiment, the connecting region 5540 of the FPCB 5400A may not be formed in the bending portion 5430. For example, the connecting layer 5420 may be omitted so as not to be disposed on the surface of each substrate layer 5410 forming the bending portion 5430.

In an embodiment, the connecting region 5540 of the FPCB 5400A may be formed at a part adjacent to the bending portion 5430. For example, the connecting layer 5420 may be disposed to bond the substrate layers 5410 of the FPCB 5400A at a part adjacent to the bending portion 5430. In an embodiment, at least one connecting region 5540 is formed on both sides (e.g., the +/−Y-axis direction of the bending portion 5430) of the bending portion 5430 based on the longitudinal direction of the FPCB 5400A so that connecting layers 5420 may be bonded with one another around the bending portion 5430. For example, in the bending portion 5430 of the FPCB 5400A, the plurality of substrate layers 5410 may not be bonded with one another, and on both sides of the bending portion 5430, the plurality of substrate layers 5410 may be bonded by the connecting layer 5420. In an embodiment, when the connecting layer 5420 is disposed not to overlap the bending portion 5430 of an FPCB 5400, the bending stiffness acting on the bending portion 5430 of the FPCB 5400 may be relatively reduced compared to when the substrate layers are bonded by the connecting layer 5420. In this case, the phenomenon of a crack occurring in a pattern of a signal line positioned at the bending portion 5430 may be reduced or prevented. Also, when the plurality of substrate layers 5410 is bonded by the connecting layer 5420 at a part adjacent to the bending portion 5430, the phenomenon of the plurality of substrate layers 5410 being excessively spread out at the bending portion 5430 may be reduced or prevented.

Referring to FIG. 5B, in the FPCB 5400B, the connecting region 5540 may not be formed in the bending portion 5430. For example, the connecting layer 5420 may be omitted from the surface of each substrate layer 5410 forming the bending portion 5430. In an embodiment, the connecting region 5540 may be formed in a part of the FPCB 5400B adjacent to the bending portion 5430. For example, based on the longitudinal direction of the FPCB 5400A, at least one connecting region 5540 is formed on both sides (e.g., the +/−Y-axis direction of the bending portion 5430) of the bending portion 5430 so that the connecting layers 5420 may be bonded around the bending portion 5430.

In an embodiment, in one connecting region 5540 formed adjacent to the bending portion 5430, each of the connecting layers 5420 disposed to overlap in the thickness direction (e.g., Z-axis) may have different areas depending on the bending shape of the bending portion 5430. For example, as illustrated in FIG. 5B, when the −Y-side end part of the bending portion 5430 of the FPCB 5400B bends in the +Z direction, a greater bending stiffness may be applied to the first substrate layer 5410a than to the third substrate layer 5410c in the connecting region 5430A positioned in the −Y direction of the bending portion 5430. In this case, a (1-1)-th connecting layer 5420a-1 has a larger area than a (2-1)-th connecting layer 5420b-1 so that the bonding areas of the first substrate layer 5410a and the second substrate layer 5410b may be formed greater than the bonding areas of the second substrate layer 5410b and the third substrate layer 5410c. Conversely, when the +Y-side end part of the bending portion 5430 of the FPCB 5400B bends in the −Z direction, a greater bending stiffness may be applied to the third substrate layer 5410c than to the first substrate layer 5410a in the connecting region 5430B positioned in the +Y direction of the bending portion 5430. In this case, a (1-2)-th connecting layer 5420a-2 has a smaller area than a (2-2)-th connecting layer 5420b-2 so that the bonding areas of the first substrate layer 5410a and the second substrate layer 5410b may be formed less than the bonding areas of the second substrate layer 5410b and the third substrate layer 5410c. For example, depending on the bending shape of the bending portion 5430 of the FPCB 5400B, the area of each connecting layer 5420 that bonds each substrate layer 5410 may be formed differently considering the bending stiffness applied to each substrate layer 5410.

Referring to FIG. 5C, in an embodiment, the connecting layers 5420a-1, 5420a-2, 5420b-1, and 5420b-2 may be disposed on a part of the FPCB 5400C adjacent to the bending portion 5430 to form a first connecting region 5540A and/or a second connecting region 5540B. For example, based on the longitudinal direction of the FPCB 5400C, the (1-1)-th connecting layer 5420a-1 and the (2-1)-th connecting layer 5420b-1 are disposed in the first connecting region 5540A positioned in the −Y-axis direction of the bending portion 5430 so that the plurality of substrate layers 5410 may be bonded with one another. The (1-2)-th connecting layer 5420a-2 and the (2-2)-th connecting layer 5420b-2 are disposed in the second connecting region 5540B positioned in the +Y-axis direction of the bending portion 5430 so that the plurality of substrate layers 5410 may be bonded with one another.

In an embodiment, the connecting layer 5420 may be disposed on at least a portion of the bending portion 5430 to form a third connecting region 5540C on the bending portion 5430. For example, in the third connecting region 5540C positioned in the bending portion 5430, a (1-3)-th connecting layer 5420a-3 and a (2-3)-th connecting layer 5420b-3 may be disposed to bond the plurality of substrate layers 5410. In an embodiment, the thickness of the connecting layers 5420a-3 and 5420b-3 disposed in the third connecting region 5540C formed in the bending portion 5430 may be relatively thinner than the connecting layers 5420a-1 and 5420b-1 disposed in the first connecting region 5540A formed adjacent to the bending portion 5430 and the connecting layers 5420a-2 and 5420b-2 disposed in the second connecting region 5540B. For example, the (1-1)-th connecting layer 5420a-1 may have a (1-1)-th thickness t1, and the (1-3)-th connecting layer 5420a-3 may have a (1-3)-th thickness t2 that is thinner than the (1-1)-th thickness t1. The (2-1)-th connecting layer 5420b-1 may have a (2-1)-th thickness t1′, and the (2-3)-th connecting layer 5420b-3 may have a (2-3)-th thickness t2′ that is thinner than the (2-1)-th thickness t1′. In an embodiment, even when the third connecting region 5540C is formed in the bending portion 5430, the third connecting region 5540C of the FPCB 5400C has a relatively thin thickness compared to the first and second connecting regions 5540A and 5540B adjacent to the bending portion 5430. As a result, the bending stiffness of the bending portion 5430 may be relatively reduced compared to the surrounding region, thereby reducing or preventing a pattern crack phenomenon of a signal line that may occur in the bending portion 5430.

In an embodiment, in at least one connecting region 5540, the connecting layers 5420 disposed to overlap in the thickness direction (e.g., Z-axis) may have different thicknesses depending on the bending stiffness of the adjacent substrate layer 5410. For example, for the first connecting region 5540A, when the bending portion 5430 adjacent to the +Y direction of the first connecting region 5540A bends in the +Z direction, a greater bending stiffness may be applied to the first substrate layer 5410a than to the third substrate layer 5410c in the first connecting region 5540A. In this case, the (2-1)-th connecting layer 5420b-1 may be formed to have a thinner thickness than the (1-1)-th connecting layer 5420a-1.

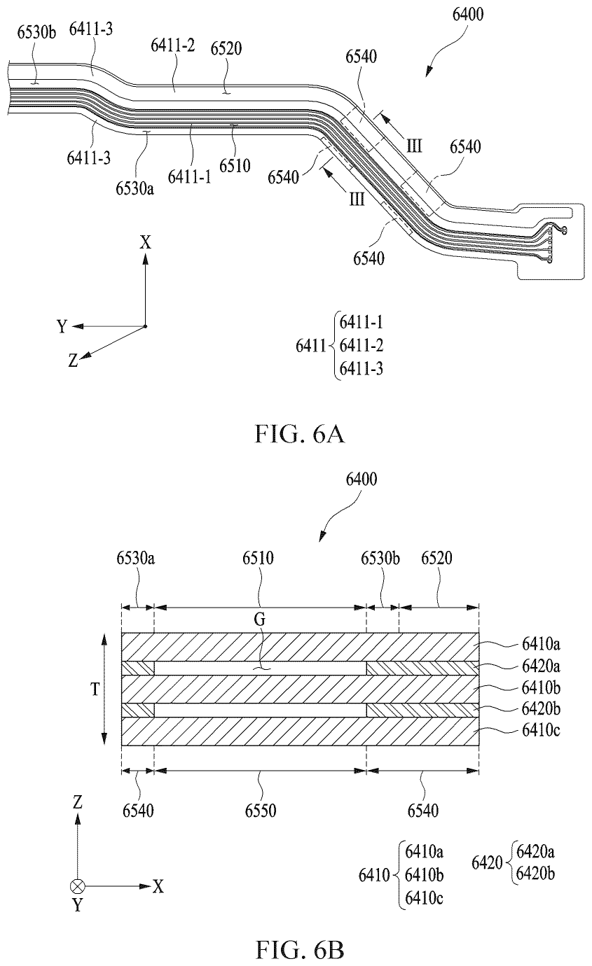

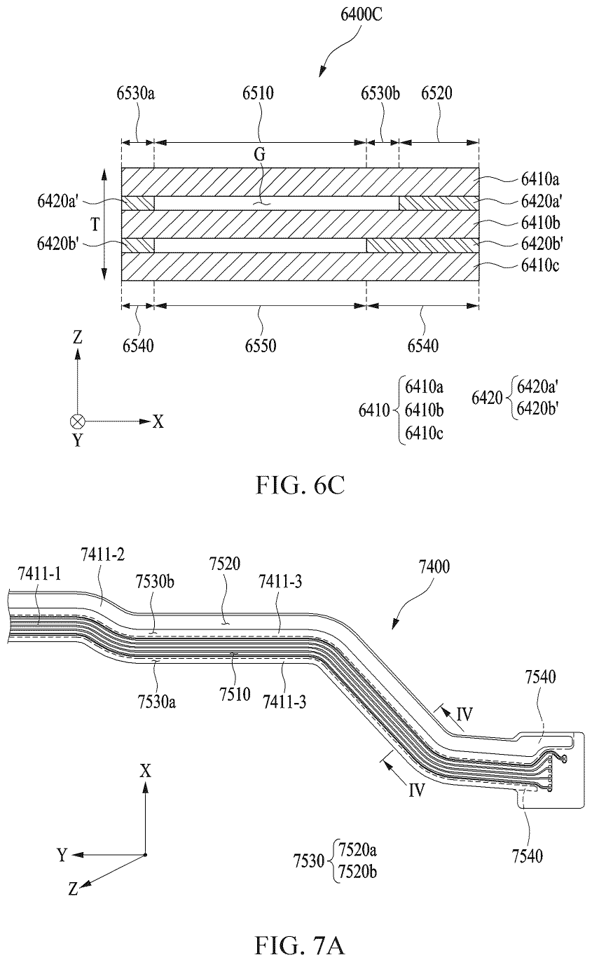

FIG. 6A is a partially enlarged view of an FPCB according to an embodiment according to an embodiment of the disclosure.

FIG. 6B is a cross-sectional view of the FPCB taken along the line III-III of FIG. 6A according to an embodiment of the disclosure.

FIG. 6C is a cross-sectional view of an FPCB taken along the line III-III of FIG. 6A according to an embodiment of the disclosure.

Referring to FIGS. 6A, 6B, and 6C, in an embodiment, FPCBs 6400 and 6400C may include a plurality of substrate layers 6410 disposed to overlap one another in the thickness direction T (e.g., the Z-axis direction) and a plurality of connecting layers 6420 that partially bond the plurality of substrate layers 6410 in the thickness direction T. For example, the plurality of substrate layers 6410 may include a first substrate layer 6410a, a second substrate layer 6410b, and a third substrate layer 6410c. For example, the plurality of connecting layers 6420 may include at least one first connecting layer 6420a disposed on at least a portion between the first substrate layer 6410a and the second substrate layer 6410b and at least one second connecting layer 6420b disposed on at least a portion between the second substrate layer 6410b and the third substrate layer 6410c.

In an embodiment, a data line 6411-1 for transmitting a data signal, a power line 6411-2 for transmitting a power signal, and a ground line 6411-3 for grounding may be formed on the surface of each substrate layer 6410. In an embodiment, when the FPCB 6400 is viewed in the thickness direction (e.g., Z-axis), the FPCB 6400 may include a first circuit region 6510 in which the data line 6411-1 is positioned, a second circuit region 6520 in which the power line 6411-2 is positioned, and a third circuit region 6530a or 6530b in which the ground line 6411-3 is positioned. In an embodiment, the third circuit region 6530a or 6530b may include the (3-1)-th circuit region 6530a positioned to the left side in the width direction (e.g., −X direction) of the first circuit region 6510 and the (3-2)-th circuit region 6530b positioned to the right side in the width direction (e.g., the +X direction) of the first circuit region 6510. For example, the (3-2)-th circuit region 6530b may be positioned between the first circuit region 6510 and the second circuit region 6520.

In an embodiment, when viewed from the surface, the FPCBs 6400 and 6400C may be divided into at least one connecting region 6540 in which at least one pair of substrate layers 6410 are bonded with each other by the connecting layer 6420 and a non-connecting region 6550 in which a plurality of substrate layers 6410 are not bonded with one another. In an embodiment, the connecting region 6540 may be formed in a part that does not overlap the first circuit region 6510 of the FPCB 6400. For example, the connecting layer 6420 may be omitted from the surface of each substrate layer 6410 on which the data line 6411-1 is formed.

In an embodiment, the connecting region 6540 of the FPCBs 6400 and 6400C may be formed at an edge in the width direction (e.g., X-axis direction) of the FPCB 6400. For example, as illustrated in FIG. 6B, based on the cross-section of a part of the FPCB 6400 in which the connecting region 6540 is positioned, a pair of connecting regions 6540 may be formed at each of the ends in the width direction of the FPCB 6400. Void spaces G may be formed between each of the substrate layers 6410a, 6410b, and 6410c in the non-connecting region 6550.

In an embodiment, based on the cross-section illustrated in FIG. 6B, the pair of connecting regions 6540 may be formed to have a width extending from an edge in the width direction of the FPCB 6400 to both ends in the width direction of the first circuit region 6510. For example, the connecting region 6540 formed on the left side of the width direction (e.g., the −X direction) of the FPCB 6400 may be formed to overlap the (3-1)-th circuit region 6530a positioned on the left side of the first circuit region 6510. In this case, the first connecting layer 6420a and the second connecting layer 6420b may have a width corresponding to the (3-1)-th circuit region 6530a of the FPCB 6400. For example, the connecting region 6540 formed on the right side in the width direction (e.g., the +X direction) of the FPCB 6400 may be formed to overlap simultaneously with the (3-2)-th circuit region 6530b and the second circuit region 6520 positioned on the right side of the first circuit region 6510. In this case, the first connecting layer 6420a and the second connecting layer 6420b may have a width substantially equal to the combined width of the (3-2)-th circuit region 6530b and the second circuit region 6520 of the FPCB 6400. For example, based on the cross-section of the FPCB 6400 illustrated in FIG. 6B, the connecting region 6540 may be formed to bond between regions of the substrate layers 6410 except for the first circuit region 6510. In the case of such a structure, it may be possible to effectively prevent the phenomenon of lifting between the substrate layers 6410 due to bending of the FPCB 6400 while reducing or preventing deterioration of data transmission performance in the FPCB 6400.

Referring to FIG. 6C, in one connecting region 6540, a first connecting layer 6420a′ and a second connecting layer 6420b′ may have the same width or different widths. For example, in the connecting region 6540 formed on the left side of the width direction (e.g., −X axis) of the FPCB 6400C, the first connecting layer 6420a′ and the second connecting layer 6420b′ may have the same width. On the other hand, in the connecting region 6540 formed on the right side in the width direction (e.g., +X axis) of the FPCB 6400C, the first connecting layer 6420a′ may be formed to be smaller in width than the second connecting layer 6420b′. However, this is only an example to describe that in one connecting region 6540, the first and second connecting layers 6420a′ and 6420b′ may have different widths, and the widths of the first and second connecting layers 6420a′ and 6420b′ positioned in the respective connecting regions 6540 are not limited the illustrated embodiment.

FIG. 7A is a partially enlarged view of an FPCB according to an embodiment of the disclosure.

FIG. 7B is a side view of the FPCB according to an embodiment of the disclosure.

FIG. 7C is a cross-sectional view of the FPCB taken along the line IV-IV of FIG. 7A according to an embodiment of the disclosure.

FIG. 7D is a cross-sectional view of the FPCB showing the region D of FIG. 7B according to an embodiment of the disclosure.

FIG. 7E is a cross-sectional view of the FPCB showing the region D of FIG. 7B according to an embodiment of the disclosure.

Referring to FIGS. 7A to 7E, an FPCB 7400 according to an embodiment may include a plurality of substrate layers 7410 that sequentially overlaps in a thickness direction T (e.g., the Z-axis direction) and a plurality of connecting layers 7420 that is disposed between the plurality of substrate layers 7410 and bonding at least a portion between adjacent substrate layers 7410. For example, the plurality of substrate layers 7410 may include a first substrate layer 7410a, a second substrate layer 7410b, and a third substrate layer 7410c. For example, the plurality of connecting layers 7420 may include a first connecting layer 7420a disposed between the first substrate layer 7410a and the second substrate layer 7410b and a second connecting layer 7420b disposed between the second substrate layer 7410b and the third substrate layer 7401c.

In an embodiment, a data line 7411-1 for transmitting a data signal, a power line 7411-2 for transmitting a power signal, and a ground line 7411-3 for grounding may be formed on the surface of each substrate layer 7410. Each circuit line (e.g., 7411-1, 7411-2, and 7411-3) may be formed to extend from a first end 7400A to a second end 7400B in the longitudinal direction of the FPCB 7400.

In an embodiment, when the FPCB 7400 is viewed in the thickness direction (e.g., Z-axis), the FPCB 7400 may include a first circuit region 7510 in which the data line 7411-1 is positioned, a second circuit region 7520 in which the power line 7411-2 is positioned, and a third circuit region 7530a or 7530b in which the ground line 7411-3 is positioned. In an embodiment, the third circuit region 7530a or 7530b may include the (3-1)-th circuit region 7530a positioned to the left side in the width direction (e.g., −X direction) of the first circuit region 7510 and the (3-2)-th circuit region 7530b positioned to the right side in the width direction (e.g., +X direction) of the first circuit region 7510. For example, the (3-2)-th circuit region 7530b may be positioned between the first circuit region 7510 and the second circuit region 7520. In an embodiment, each of the circuit regions 7510, 7520, and 7530 may extend in the longitudinal direction of the FPCB 7400.

In an embodiment, when viewed from the surface, the FPCB 7400 may be divided into a connecting region 7540 in which at least one pair of substrate layers 7410 are bonded with each other by a connecting layer 7420 and a non-connecting region 7550 in which the substrate layers 7410 are not bonded with one another. For example, the connecting layer 7420 may be disposed in a part of the FPCB 7400 corresponding to the connecting region 7540.

In an embodiment, the connecting region 7540 in the FPCB 7400 may be formed at a position that does not overlap the first circuit region 7510. For example, the connecting layer 7420 may be omitted from the surface of each substrate layer 7410 on which the data line 7411-1 is formed. In an embodiment, the connecting region 7540 may be formed in a shape extending in the longitudinal direction of the FPCB 7400. For example, as illustrated in FIG. 7B, the connecting layer 7420 may be disposed to bond the plurality of substrate layers 7410 in the longitudinal direction of the FPCB 7400 without overlapping the first circuit region 7510.

In an embodiment, the connecting region 7540 may be formed to overlap the remaining region of the FPCB 7400 excluding the first circuit region 7510. For example, as illustrated in FIG. 7A, when the surface of the FPCB 7400 is viewed, the non-connecting region 7550 from which the connecting layer 7420 is omitted may be formed in a part corresponding to the first circuit region 7510, and the connecting layer 7420 may be disposed in parts corresponding to the second circuit region 7520 and the third circuit region 7530 so that the connecting region 7540 in which the substrate layers 7410 are bonded with one another may be formed. In an embodiment, when the second circuit region 7520 and the third circuit region 7530 extend in the longitudinal direction of the FPCB 7400, the connecting region 7540 may be formed integrally in the longitudinal direction of the FPCB 7400 by wrapping around the edge of the first circuit region 7510. Void spaces G may be formed between the substrate layers 7410 corresponding to a part in which the non-connecting region 7550 is formed, for example, the first circuit region 7510.

Referring to FIG. 7C, based on the cross-section in the width direction of the FPCB 7400, when the (3-1)-th circuit region 7530a is positioned on the left side (e.g., the −X direction) of the first circuit region 7510, the first connecting layer 7420a and the second connecting layer 7420b having widths that are substantially the same as the width of the (3-1)-th circuit region 7530a may be disposed in a part of the FPCB 7400 corresponding to the (3-1)-th circuit region 7530a to form the connecting region 7540. When the (3-2)-th circuit region 7530b and the second circuit region 7520 are positioned on the right side (e.g., the +X direction) of the second circuit region 7520, the first connecting layer 7420a and the second connecting layer 7420b having widths that are substantially the same as the width connecting the (3-2)-th circuit region 7530b to the second circuit region 7520 may be disposed on the right side of the first circuit region 7510 to form the connecting region 7540. However, this is only an example, and the connecting region 7540 is not necessarily formed in the entire remaining region of the FPCB 7400 excluding the first circuit region 7510. For example, the connecting region 7540 may be omitted from the (3-2)-th circuit region 7530b. For example, the connecting region 7540 may be formed to overlap at least a portion of the (3-1)-th circuit region 7530a and the second circuit region 7520. For example, the connecting region 7540 may be formed in a form that extends integrally in the longitudinal direction of the FPCB 7400 and may be formed in various arrangements so as to bond the substrate layers 7410 with one another.

In an embodiment, in the FPCB 7400, when the connecting region 7540 is formed integrally in the longitudinal direction of the FPCB 7400 without overlapping the first circuit region 7510, for example, when the connecting layer 7420 bonds the substrate layers 7410 in the longitudinal direction of the FPCB 7400, a phenomenon in which data transmission performance of the data line 7411-1 formed in each of the substrate layers 7410 is deteriorated may be reduced or prevented, while maintaining a constant spacing between the substrate layers 7410 of the FPCB 7400.

In an embodiment, a plurality of slits 74201 may be formed in at least a portion of the connecting layer 7420. For example, as illustrated in FIG. 7D, the plurality of slits 74201 is formed in the connecting layer 7420 disposed at a bending portion of the FPCB 7400 so that adjacent substrate layers 7410 may be partially bonded. The shape of the connecting layer 7420 illustrated in FIG. 7D is an example, and the width of the plurality of slits 74201 formed in the connecting layer 7420 and the width-direction (e.g., X-axis direction) spacing between the plurality of slits 74201 may be formed differently depending on the degree of bending of each bending portion. For example, as the degree of bending of the bending portion increases, the widths of the slits 74201 increase and the gaps between the slits 74201 narrow, which may reduce the bending stiffness of a corresponding bending portion. In FIG. 7D, the spacing and width of each slit 74201 are illustrated as being constant. However, this is only an example, and at least some of the plurality of slits 74201 may have different widths, and the spacing between the slits 74201 may also be formed differently.

In an embodiment, as illustrated in FIG. 7E, at least a portion of the connecting layer 7420 may have a plurality of recesses 74202 formed therein. For example, a plurality of partially concave recesses 74202 may be formed in a part of a connecting layer 7420 positioned at a bending portion of a FPCB 7400. The width of each recess 74202 and the spacing between adjacent recesses 74202 may be formed differently depending on the degree of bending of the bending portion of the corresponding FPCB 7400. In an embodiment, in a part (e.g., FIG. 7C) in which the FPCB 7400 does not bend, a slit or a recess may not formed in the connecting layer 7420.

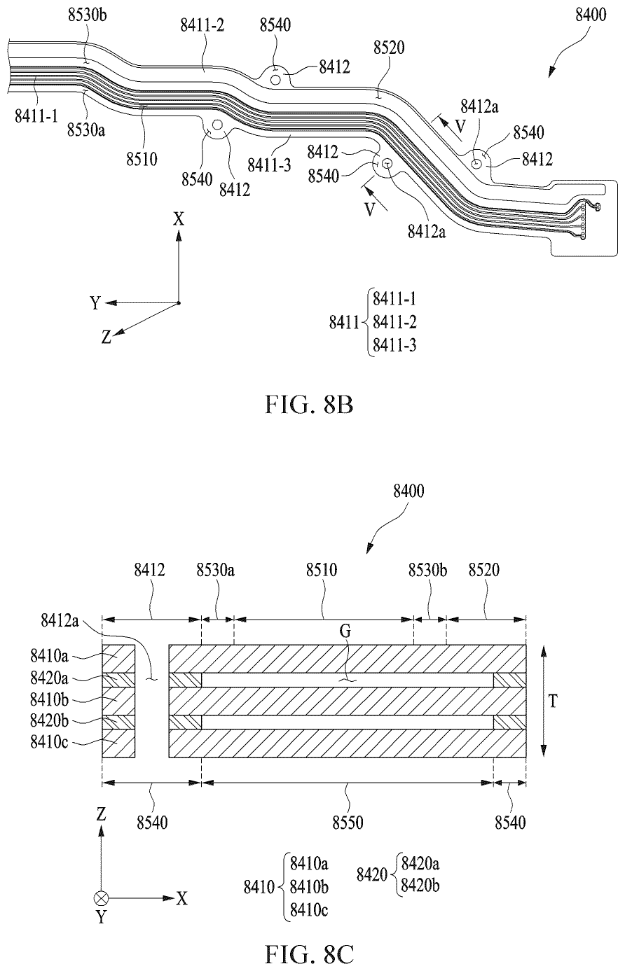

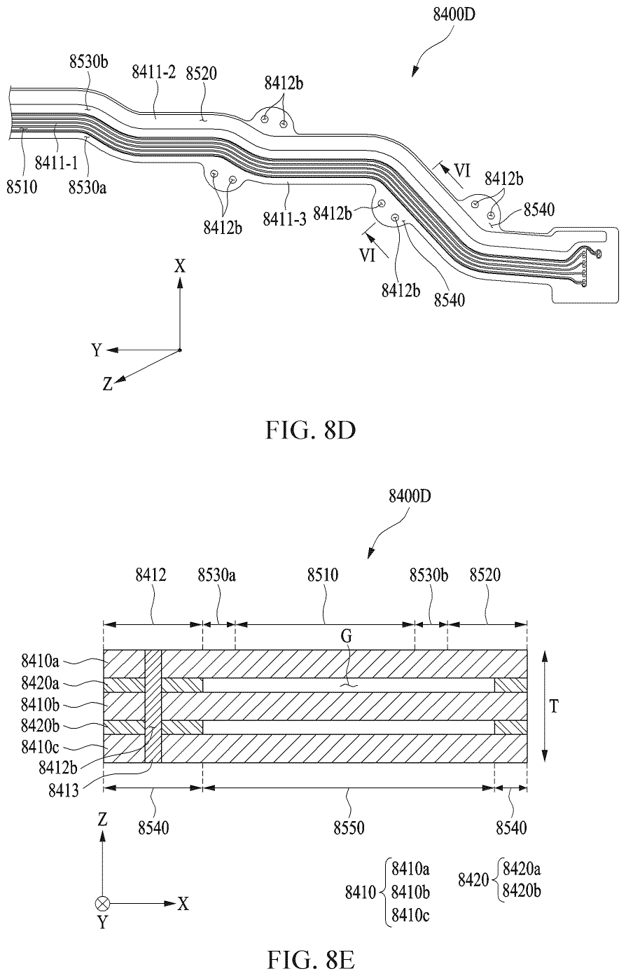

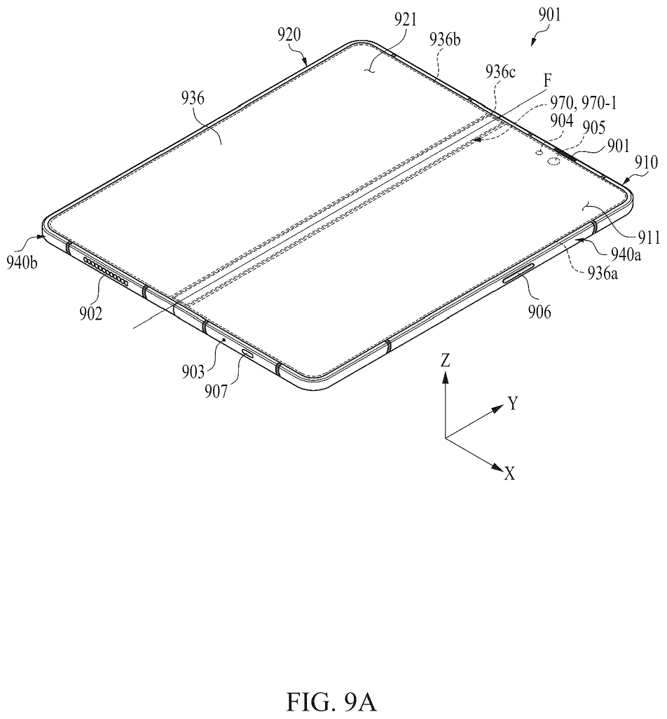

FIG. 8A is a see-through perspective view of a wearable electronic device according to an embodiment of the disclosure.

FIG. 8B is a partially enlarged view of the region C of an FPCB of FIG. 8A according to an embodiment of the disclosure.

FIG. 8C is a cross-sectional view of the FPCB taken along the line V-V of FIG. 8B according to an embodiment of the disclosure.

FIG. 8D is a partially enlarged view of the region C of the FPCB of FIG. 8A according to an embodiment of the disclosure.

FIG. 8E is a cross-sectional view of the FPCB taken along the line VI-VI of FIG. 8D according to an embodiment of the disclosure.

Referring to FIGS. 8A to 8E, a wearable electronic device 801 (e.g., the electronic device 201 of FIG. 1, the wearable electronic device 201 of FIG. 2, and the wearable electronic device 301 of FIG. 3A) according to an embodiment may include a housing 800 forming the exterior of the wearable electronic device 801 and FPCBs 8400 and 8400D disposed in the housing 800.

In an embodiment, the housing 800 may include a frame 8100 (e.g., the frame 4100 of FIG. 4A) and a temple 8200 (e.g., the temple 4200 of FIG. 4A). In an embodiment, at least one electronic component may be disposed in the housing 800. For example, the wearable electronic device 801 may include a PCB 8408 (e.g., the PCB 4408 of FIG. 4A) disposed in the frame 8100 and having at least one component element mounted thereon. A processor (e.g., the processor 120 of FIG. 1) for controlling the operation of the wearable electronic device 801 may be disposed on the PCB 8408, for example. In an embodiment, the wearable electronic device 801 may include at least one connecting terminal 8409 (e.g., the connecting terminal 4409 of FIG. 4A) to be connected to an external electronic device and/or an external power source.

In an embodiment, the FPCBs 8400 and 8400D may electrically connect two or more elements in the wearable electronic device 801. For example, the FPCB 8400 may be positioned across the frame 8100 and the temple 8200 of the wearable electronic device 801. The FPCB 8400 may have, for example, a first end 8400A connected to the PCB 8408 and a second end 8400B connected to the connecting terminal 8409. In an embodiment, the FPCB 8400 may be formed to be flexible so as to be bendable. In an embodiment, the FPCB 8400 may be at least partially secured within the housing 800 by a connecting member (not shown) such that the arrangement of the FPCB 8400 within the housing 800 is fixed.

Referring to FIGS. 8B and 8C, in an embodiment, the FPCB 8400 may include a plurality of substrate layers 8410 disposed to overlap in a thickness direction T (e.g., Z-axis) and a plurality of connecting layers 8420 that partially connects the plurality of substrate layers 8410 in the thickness direction T. For example, the plurality of substrate layers 8410 may include a first substrate layer 8410a, a second substrate layer 8410b, and a third substrate layer 8410c. For example, the plurality of connecting layers 8420 may include at least one first connecting layer 8420a disposed between the first substrate layer 8410a and the second substrate layer 8410b and at least one second connecting layer 8420b disposed between the second substrate layer 8410b and the third substrate layer 8410c.

In an embodiment, a data line 8411-1 for transmitting a data signal, a power line 8411-2 for transmitting a power signal, and a ground line 8411-3 for grounding may be formed on the surface of each substrate layer 8410. In an embodiment, when the FPCB 8400 is viewed in the thickness direction (e.g., Z-axis), the FPCB 8400 may include a first circuit region 8510 in which the data line 8411-1 is positioned, a second circuit region 8520 in which the power line 8411-2 is positioned, and a third circuit region 8530a or 8530b in which the ground line 8411-3 is positioned. In an embodiment, the third circuit region 8530a or 8530b may include the (3-1)-th circuit region 8530a positioned to the left side in the width direction (e.g., −X direction) of the first circuit region 8510 and the (3-2)-th circuit region 8530b positioned to the right side in the width direction (e.g., +X direction) of the first circuit region 8510. For example, the (3-2)-th circuit region 8530b may be positioned between the first circuit region 8510 and the second circuit region 8520.

In an embodiment, the FPCB 8400 may include at least one protruding portion 8412 that protrudes outwardly in the width direction (e.g., X axis) perpendicular to the longitudinal direction. In an embodiment, at least one protruding portion 8412 may be used to secure the arrangement of the FPCB 8400 relative to the housing 800. For example, the FPCB 8400 may be secured inside the housing 800 through the protruding portion 8412. In an embodiment, each protruding portion 8412 may include at least one guide hole 8412a formed in the thickness direction T. For example, the guide hole 8412a may be used to insert a guide member (not shown) (e.g., a screw) to secure the FPCB 8400 when the FPCB 8400 is installed in the housing 800.

In an embodiment, when the surface of the FPCB 8400 is viewed, the FPCB 8400 may be divided into at least one connecting region 8540 in which at least one pair of substrate layers 8410 are bonded with each other by the connecting layer 8420 and a non-connecting region 8550 in which the substrate layers 8410 are not bonded with one another. In an embodiment, the connecting region 8540 may be formed in a part that does not overlap the first circuit region 8510 of the FPCB 8400. For example, the connecting layer 8420 may be omitted from the surface of each substrate layer 8410 on which the data line 8411-1 is formed.

In an embodiment, the connecting region 8540 in the FPCB 8400 may be formed in the protruding portion 8412. For example, in the protruding portion 8412, the plurality of substrate layers 8410 may be bonded as one entity through the plurality of connecting layers 8420. In an embodiment, when the guide hole 8412a is formed in the protruding portion 8412, the guide hole 8412a may be formed by penetrating the plurality of substrate layers 8410 and the connecting layer 8420 forming the protruding portion 8412.

In an embodiment, as illustrated in FIG. 8C, when the protruding portion 8412 is formed at an end of the FPCB 8400 in the width direction (e.g., a −X direction end), the connecting layers 8420a and 8420b disposed on the left side in the width direction (e.g., a −X direction end) of the FPCB 8400 may be disposed to overlap only the substrate layers 8410a, 8410b, and 8410c forming the protruding portion 8412. In this case, the non-connecting region 8550 may be formed in the (3-1)-th circuit region 8530a. As illustrated in FIG. 8C, when the protruding portion 8412 is not formed on the right side in the width direction (e.g., +X direction end) of the FPCB 8400, the connecting layers 8420 may be disposed in at least a portion of the second circuit region 8520 and/or the (3-2)-th circuit region 8530b to form the connecting region 8540. Void spaces G may be formed between the substrate layers 8410 corresponding to the non-connecting region 8550.

Referring to FIG. 8C, a case is provided as an example in which the connecting region 8540 is formed in a portion of the second circuit region 8520 positioned on the right side of the first circuit region 8510, but, alternatively, in the FPCB 8400, the connecting region 8540 may be formed only in the protruding portion 8412. According to this structure, parts of a substrate layer in which a circuit pattern is formed in the FPCB 8400 may be formed as the non-connecting region 8550 and separated from each other, so the deterioration of signal transmission performance may be minimized or prevented. In addition, since the substrate layers 8410 are bonded with one another only at the protruding portion 8412, the phenomenon of lifting and shaking between the plurality of substrate layers 8410 may be reduced or prevented.

Referring to FIGS. 8D and 8E, in an embodiment, the FPCB 8400D may include at least one via hole 8812b formed in the protruding portion 8412. In an embodiment, at least one via hole 8412b may be formed to penetrate the protruding portion 8412 in the thickness direction T. In an embodiment, the via hole 8412b may function as a ground path to connect the FPCB 8400D to the ground of the wearable electronic device 801. For example, the via hole 8412b may be filled with a metal material of a conductive material (e.g., copper). In an embodiment, when the protruding portion 8412 is formed as the connecting region 8540, for example, when the substrate layers 8410 are bonded with one another by the connecting layer 8420, the metal material filled in the via hole 8412b may reinforce the bonding strength of the plurality of substrate layers 8410 and the connecting layers 8420 in the protruding portion 8412 of the FPCB.

Hereinafter, an embodiment of various types of electronic devices is described. In describing an embodiment of each of the various types of electronic devices, it is apparent to those skilled in the art that the structures of various embodiments of an FPCB described above, for example, embodiments of the FPCB, in which substrate layers are partially bonded with one another via a connecting layer, may be applied to the various types of electronic devices described below. For example, the embodiments of the FPCBs described with reference to FIGS. 4A to 4J, 5A to 5C, 6A to 6C, 7A to 7E, and 8A to 8E may be easily changed, modified, and combined by those skilled in the art and applied identically or similarly to the following electronic devices.

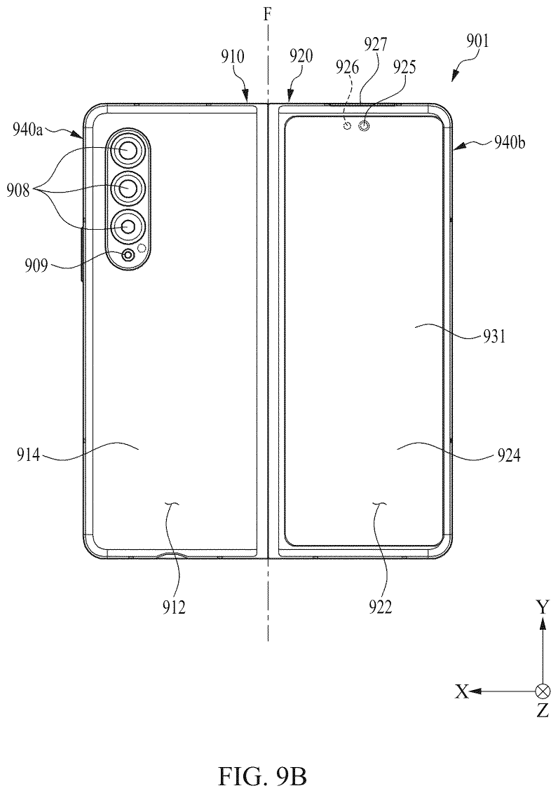

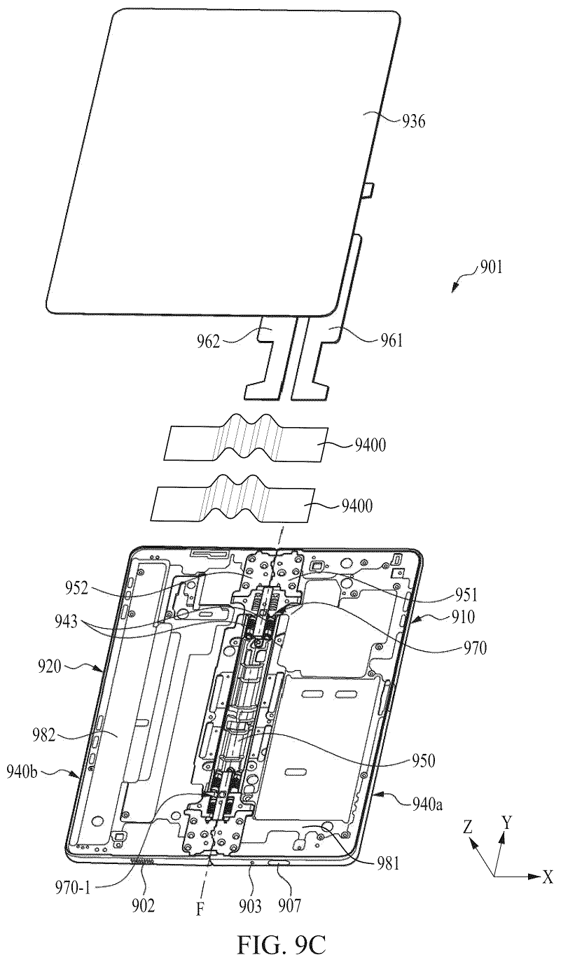

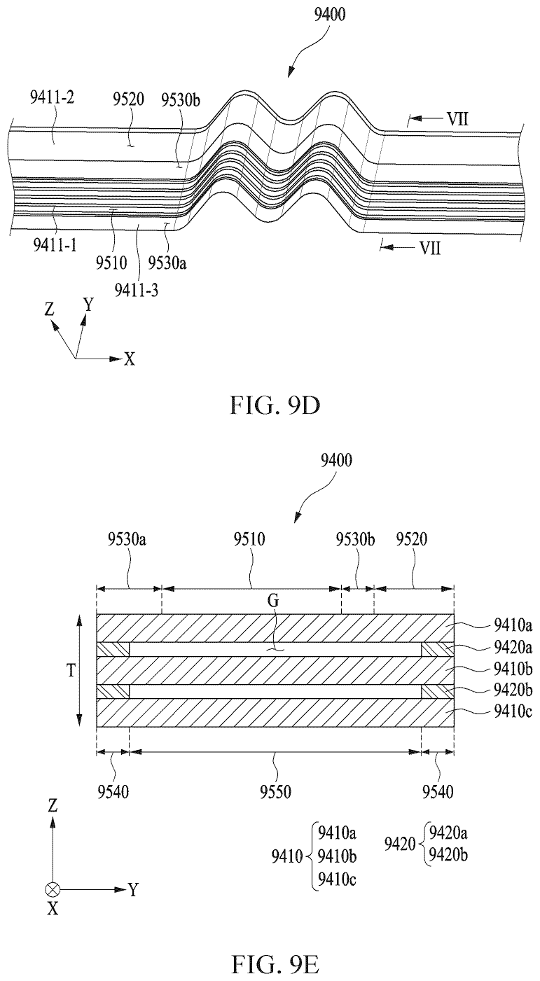

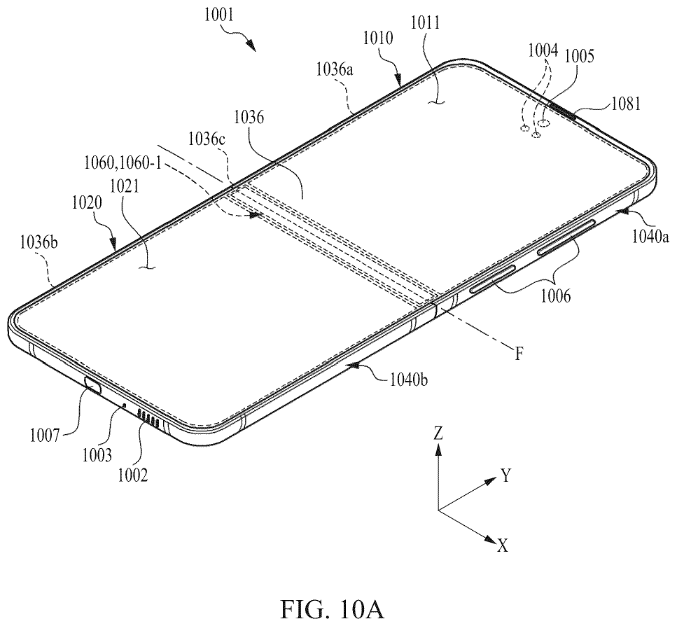

FIG. 9A is a front perspective view of an electronic device according to an embodiment of the disclosure.

FIG. 9B is a rear view of the electronic device according to an embodiment of the disclosure.

FIG. 9C is an exploded perspective view of the electronic device according to an embodiment of the disclosure.

FIG. 9D is a partial perspective view of an FPCB according to an embodiment of the disclosure.

FIG. 9E is a cross-sectional view of the FPCB taken along the line VII-VII of FIG. 9D according to an embodiment of the disclosure.

Referring to FIGS. 9A, 9B, and 9C, an electronic device 901 (e.g., the electronic device 101 of FIG. 1) according to an embodiment may include a first housing 910 (e.g., a first housing structure) and a second housing 920 (e.g., a second housing structure) that are foldable with respect to each other via at least one hinge device 970 or 970-1 (e.g., a hinge module or a hinge structure) with respect to a folding axis F. For example, the first housing 910 and the second housing 920 may be configured as a foldable housing (e.g., a housing structure). In an embodiment, the first housing 910 may include a first surface 911 and a second surface 912 facing an opposite direction (e.g., the −Z direction of FIG. 9A) of the first surface 911. The second housing 920 may include a third surface 921 and a fourth surface 922 facing an opposite direction (e.g., the −Z direction of FIG. 9A) of the third surface 921. In an embodiment, the first housing 910 may include a first side surface formed between the first surface 911 and the second surface 912. The second housing 920 may include a second side surface formed between the third surface 921 and the fourth surface 922.

In an embodiment, the first housing 910 may include a first side member 940a (e.g., a first side bezel) forming at least a portion of the first side surface. The first side member 940a may include a conductive portion. In an embodiment, the first housing 910 may include a first rear cover 914 coupled with the first side member 940a and forming the second surface 912. In an embodiment, the second housing 920 may include a second side member 940b (e.g., a second side bezel) forming at least a portion of the second side surface. The second side member 940b may include a conductive portion. In an embodiment, the second housing 920 may include a second rear cover 924 coupled with the second side member 940b and forming the fourth surface 922.

In an embodiment, the shape of the electronic device 901 may change as the relative angle between the first housing 910 and the second housing 920 changes around the folding axis F. For example, the shape of the electronic device 901 may change between a first state (e.g., an unfolded state) in which the first surface 911 and the second surface 912 are fully unfolded so that the first surface 911 and the second surface 912 are positioned on substantially the same plane and a second state (e.g., a folded state) in which the first surface 911 and the second surface 912 are fully folded inward so that the first surface 911 and the second surface 912 face each other or fully folded outward so that the first surface 911 and the second surface 912 face opposite directions. In an embodiment, the electronic device 901 may operate to have a third state (e.g., an intermediate unfolded state) between the first state and the second state.

In an embodiment, the electronic device 901 may include a first receiver 9010, at least one first sensor module 904 (e.g., a light sensor), and/or at least one first camera module 905 (e.g., an under display camera (UDC)) disposed through the first surface 911 of the first housing 910. In an embodiment, the electronic device 901 may include at least one button 906 formed on the first side member 940a. In an embodiment, the electronic device 901 may include at least one second camera module 908 and/or a flash 909 disposed through the second surface 912 (e.g., the first rear cover 914) of the first housing 910.

In an embodiment, the electronic device 901 may include a first display 936 (e.g., a flexible display, a foldable display, or a main display) supported by the first housing 910 and the second housing 920 and disposed to be visually displayed through the first surface 911 and the third surface 921.

In an embodiment, the first display 936 may include a first region 936a (e.g., a first flat portion) corresponding to at least a portion of the first surface 911, a second region 936b (e.g., a second flat portion) corresponding to at least a portion of the third surface 921, and a folding region 936c (e.g., a folding portion) that connects the first region 936a to the second region 936b and has a shape that changes during the folding process of the electronic device 901. In an embodiment, when the first display 936 is viewed from the top (e.g., the +Z direction of FIG. 9A), the folding region 936c may be disposed at a position that at least partially overlaps at least one hinge device 970, 970-1. For example, the first display 936 may be disposed so as not to be visible from the outside in the second state of the electronic device 901 in which the first surface 911 and the third surface 921 face each other (e.g., in the case of an in-folding type). For example, the first display 936 may be disposed to be visible to the outside in the second state of the electronic device 901 in which the first surface 911 and the third surface 921 face in opposite directions (e.g., in the case of an out-folding type).

In an embodiment, the electronic device 901 may include a second display 931 (e.g., an auxiliary display) disposed through the fourth surface 922 of the second housing 920, at least one third camera module 925, at least one second sensor module 926, and/or a second receiver 927. For example, the second display 931 may be disposed to be visible from the outside through at least a portion of the second rear cover 924.

In an embodiment, the electronic device 901 may include a speaker 902 disposed through the second side member 940b, a microphone 903 disposed through the first side member 940a, and/or a connector port 907. The arrangement of at least some of the components described above may be changed and/or modified between the first housing 910 and/or the second housing 920.

In an embodiment, at least one hinge device 970 or 970-1 may be disposed at the bottom (e.g., the −Z direction of FIG. 8C) of the first display 936 and may connect the first housing 910 to the second housing 920. For example, at least one hinge device 970 or 970-1 may include a first hinge device 970 disposed along the folding axis F and a second hinge device 970-1 disposed to be spaced apart from the first hinge device 970. In an embodiment, the first hinge device 970 may be formed in a configuration that is substantially symmetrical or substantially identical to the second hinge device 970-1. For example, at least one hinge device 970 or 970-1 may be supported by a first support member 981 extending from the first side member 940a to a first space of the first housing 910 and a second support member 982 extending from the second side member 940b to a second space of the second housing 920. In an embodiment, at least one hinge device 970 or 970-1 may be covered by a hinge housing 950 between the first housing 910 and the second housing 920 and may not be visible from the outside.

In an embodiment, the first hinge device 970 or 970-1 may include a first rotating member 951 (e.g., a first arm or a first rotator) disposed on the first support member 981 of the first housing 910, a second rotating member 952 (e.g., a second arm or a second rotator) disposed on the second support member 982 of the second housing 920, and a gear assembly 943 that connects the first rotating member 951 to the second rotating member 952 and symmetrically rotates the first housing 910 and the second housing 920 relative to each other. For example, a gear assembly may include a plurality of gears (e.g., spur gears and/or worm gears) that are gear-engaged with respect to one another. For example, the gear assembly may include a cam coupling structure and/or a spring structure for pressing the first housing 910 and the second housing 920 to transition in a direction from the first state to the second state or in a direction from the second state to the first state based on a predetermined angle relative to each other.

In an embodiment, the electronic device 901 may be coupled with at least one hinge device 970, 970-1 and may include at least one detent module to provide a stopping sensation at various folding angles of the electronic device 901. For example, at least one hinge device 970 or 970-1 and/or detent module may form substantially the same plane as the first support member and the second support member when the electronic device 901 is in the first state.

In an embodiment, the electronic device 901 may include a first hinge plate 961 connected to the first support member 981 and/or the first rotating member 951. The electronic device 901 may include a second hinge plate 962 connected to the second support member 982 and/or the second rotating member 952. For example, at least one hinge device 970, 970-1, the first rotating member 951, the second rotating member 952, the first hinge plate 961, and the second hinge plate 962 may form substantially the same plane as the first support member 981 and the second support member 982 when the electronic device 901 is in the first state.

In an embodiment, the electronic device 901 may further include at least one FPCB 9400 disposed in the electronic device 901. In an embodiment, the FPCB 9400 may be disposed to extend from the first housing 910 of the electronic device 901 to the second housing 920 across the folding axis F. In an embodiment, the FPCB 9400 may electrically connect a component element (e.g., a first PCB disposed in the first housing 910) disposed in the first housing 910 to a component element (e.g., a second PCB disposed in the second housing 920) disposed in the second housing 920. In an embodiment, the FPCB 9400 may be formed to be at least partially flexible and may at least partially bend to conform to a change in the shape of the electronic device 901 when the electronic device 901 changes between the first state and the second state.

Referring to FIGS. 9D and 9E, the FPCB 9400 according to an embodiment may be formed in a structure in which a plurality of layers overlap one another in the thickness direction T (e.g., Z-axis) of the FPCB 9400. In an embodiment, the FPCB 9400 may include a plurality of substrate layers 9410 sequentially disposed to overlap one another in the thickness direction T and a plurality of connecting layers 9420 disposed between the plurality of substrate layers 9410 and bonding at least a portion between adjacent substrate layers 9410. For example, the plurality of substrate layers 9410 may include a first substrate layer 9410a, a second substrate layer 9410b, and a third substrate layer 9410c. For example, the plurality of connecting layers 9420 may include at least one first connecting layer 9420a disposed between the first substrate layer 9410a and the second substrate layer 9410b and a second connecting layer 9420b disposed between the second substrate layer 9410b and the third substrate layer 9410c.

In an embodiment, a data line 9411-1 for transmitting a data signal, a power line 9411-2 for transmitting a power signal, and a ground line 9411-3 for grounding may be formed on the surface of each substrate layer 9410. In an embodiment, when the FPCB 9400 is viewed in the thickness direction (e.g., Z-axis), the FPCB 9400 may include a first circuit region 9510 in which the data line 9411-1 is positioned, a second circuit region 9520 in which the power line 9411-2 is positioned, and a third circuit region 9530a or 9530b in which the ground line 9411-3 is positioned.

In an embodiment, when the surface of the FPCB 9400 is viewed, the FPCB 9400 may be divided into at least one connecting region 9540 in which at least one pair of substrate layers 9410 are bonded with each other by the connecting layer 9420 and a non-connecting region 9550 in which the substrate layers 9410 are not bonded with one another. For example, it may be understood that the connecting layer 9420 is disposed in a part of the FPCB 9400 corresponding to the connecting region 9540. In an embodiment, the connecting region 9540 may be formed in a part that does not overlap the first circuit region 9510 of the FPCB 9400. For example, the connecting layer 9420 may be omitted from the surface of each substrate layer 9410 on which the data line 9411-1 is formed. In an embodiment, the connecting region 9540 may be formed in the second circuit region 9520 and/or the third circuit region 9530 of the FPCB 9400. Based on the cross-section of the FPCB 9400 as illustrated in FIG. 9E, the connecting region 9540 may be formed only in a portion of the second circuit region 9520 but may alternatively be entirely formed in the second circuit region 9520. In a part of the FPCB 9400 corresponding to the non-connecting region 9550, void spaces G may be formed between the substrate layers 9410.

In an embodiment, when the connecting region 9540 of the FPCB 9400 is formed in a part that does not overlap the first circuit region 9510, the phenomenon of deterioration in the transmission performance of a data signal through data lines 9411-1 of respective substrate layers 9410 of the FPCB 9400 may be reduced or prevented. At the same time, since the respective substrate layers 9410 of the FPCB 9400 are partially bonded through the connecting region 9540, when the FPCB 9400 bends according to the folding operation of the electronic device 901, the phenomenon of gaps between the respective substrate layers 9410 becoming excessively wide may be reduced or prevented.

In an embodiment, the arrangement structure of the connecting region 9540 and the non-connecting region 9550 formed on the FPCB 9400 may be implemented through various embodiments of the FPCB illustrated in FIGS. 4A to 4J, 5A to 5C, 6A to 6C, 7A to 7E, and 8A to 8E described above.

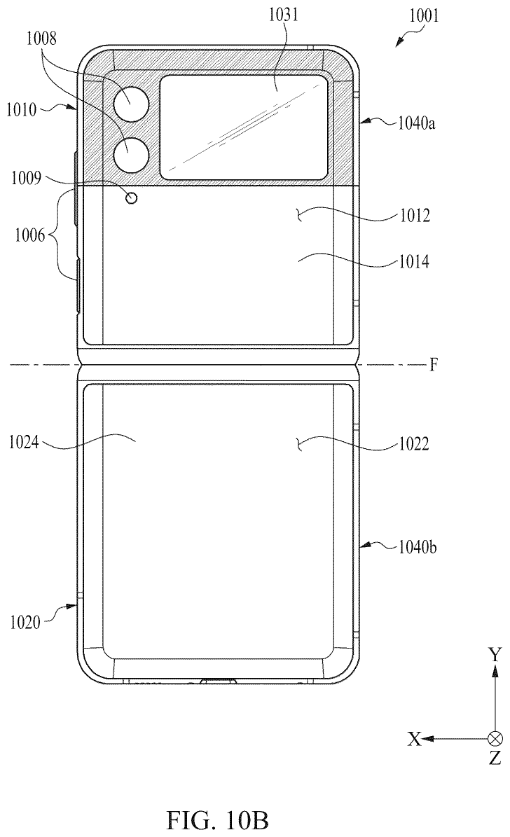

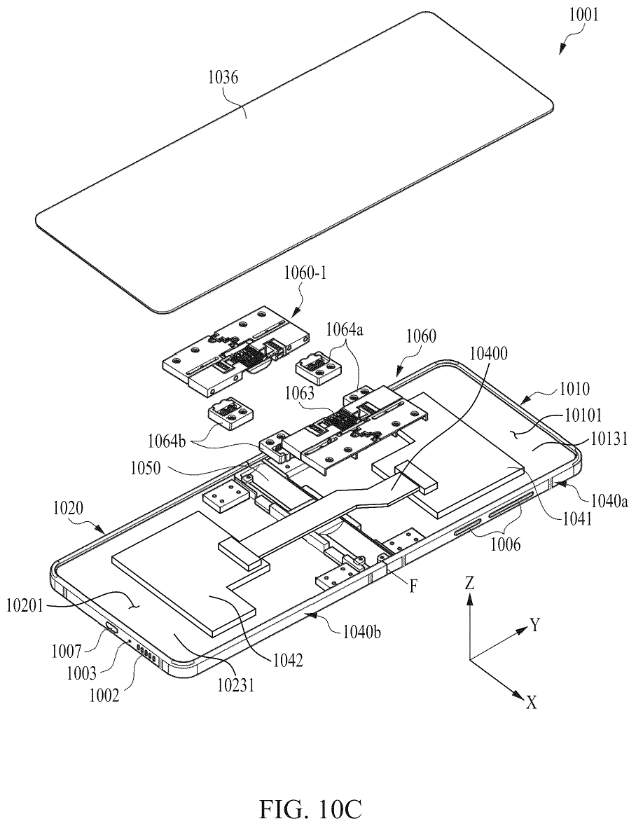

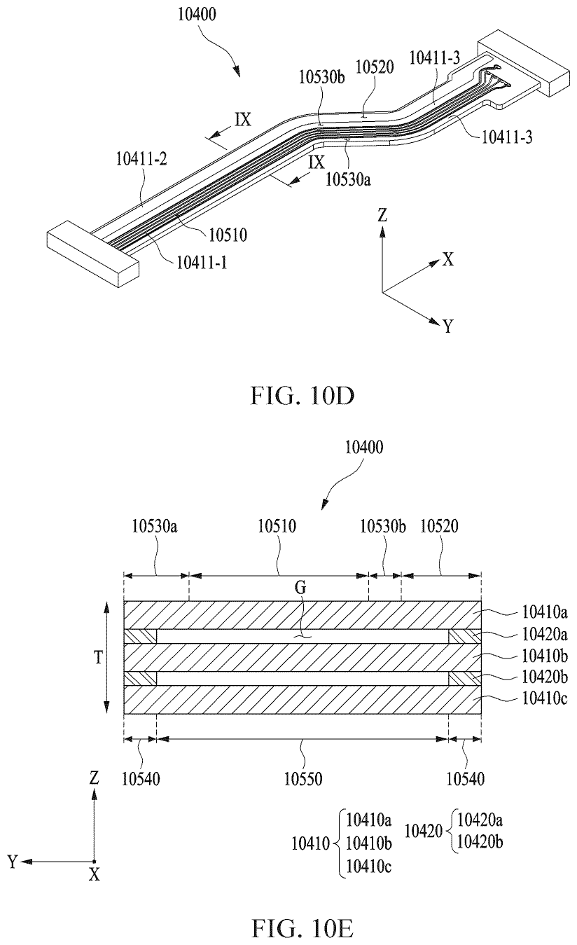

FIG. 10A is a front perspective view of an electronic device according to an embodiment of the disclosure.

FIG. 10B is a rear view of the electronic device according to an embodiment of the disclosure.

FIG. 10C is an exploded perspective view of the electronic device according to an embodiment of the disclosure.

FIG. 10D is a perspective view of an FPCB according to an embodiment of the disclosure.

FIG. 10E is a cross-sectional view of the FPCB taken along the line IX-IX of FIG. 10D according to an embodiment of the disclosure.

Referring to FIGS. 10A, 10B, and 10C, an electronic device 1001 (e.g., the electronic device 101 of FIG. 1) according to an embodiment may include a first housing 1010 (e.g., a first housing structure) and a second housing 1020 (e.g., a second housing structure) that are foldable with respect to each other via at least one hinge device 1060, 1060-1 (e.g., a hinge module or a hinge structure) with respect to a folding axis F. For example, the first housing 1010 and the second housing 1020 may be configured as a foldable housing (e.g., a housing structure). In an embodiment, the first housing 1010 may include a first surface 1011 and a second surface 1012 facing an opposite direction (e.g., the −Z direction of FIG. 10A) of the first surface 1011. The second housing 1020 may include a third surface 1021 and a fourth surface 1022 facing an opposite direction (e.g., the −Z direction of FIG. 10A) of the third surface 1021. In an embodiment, the first housing 1010 may include a first side surface formed between the first surface 1011 and the second surface 1012. The second housing 1020 may include a second side surface formed between the third surface 1021 and the fourth surface 1022.

In an embodiment, the first housing 1010 may include a first side member 1040a (e.g., a first side bezel) forming at least a portion of the first side surface. The first side member 1040a may include a conductive portion. In an embodiment, the first housing 1010 may include a first rear cover 1014 coupled with the first side member 1040a and forming the second surface 1012. In an embodiment, the second housing 1020 may include a second side member 1040b (e.g., a second side bezel) forming at least a portion of the second side surface. The second side member 1040b may include a conductive portion. In an embodiment, the second housing 1020 may include a second rear cover 1024 coupled with the second side member 1040b and forming the fourth surface 1022.

In an embodiment, the shape of the electronic device 1001 may change as the relative angle between the first housing 1010 and the second housing 1020 changes around the folding axis F. For example, the shape of the electronic device 1001 may change between a first state (e.g., an unfolded state) in which the first surface 1011 and the second surface 1012 are fully unfolded so that the first surface 1011 and the second surface 1012 are positioned on substantially the same plane and a second state (e.g., a folded state) in which the first surface 1011 and the second surface 1012 are fully folded inward so that the first surface 1011 and the second surface 1012 face each other or fully folded outward so that the first surface 1011 and the second surface 1012 face opposite directions. In an embodiment, the electronic device 1001 may operate to have a third state (e.g., an intermediate unfolded state) between the first state and the second state.

In an embodiment, the electronic device 1001 may include a first receiver 1081, at least one first sensor module 1004 (e.g., a light sensor), and/or at least one first camera module 1005 (e.g., a UDC) disposed through the first surface 1011 of the first housing 1010. In an embodiment, the electronic device 1001 may include at least one button 1006 formed on the first side member 1040a. In an embodiment, the electronic device 1001 may include at least one second camera module 1008 and/or a flash 1009 disposed through the second surface 1012 (e.g., the first rear cover 1014) of the first housing 1010.

In an embodiment, the electronic device 1001 may include a first display 1036 (e.g., a flexible display, a foldable display, or a main display) supported by the first housing 1010 and the second housing 1020 and disposed to be visually displayed through the first surface 1011 and the third surface 1021.

In an embodiment, the first display 1036 may include a first region 1036a (e.g., a first flat portion) corresponding to at least a portion of the first surface 1011, a second region 1036b (e.g., a second flat portion) corresponding to at least a portion of the third surface 1021, and a folding region 1036c (e.g., a folding portion) that connects the first region 1036a to the second region 1036b and has a shape that changes during the folding process of the electronic device 1001. In an embodiment, when the first display 1036 is viewed from the top (e.g., the +Z direction of FIG. 10A), the folding region 1036c may be disposed at a position that at least partially overlaps at least one hinge device 1060 or 1060-1. For example, the first display 1036 may be disposed so as not to be visible from the outside in the second state of the electronic device 1001 in which the first surface 1011 and the third surface 1021 face each other (e.g., in the case of an in-folding type). For example, the first display 1036 may be disposed to be visible to the outside in the second state of the electronic device 1001 in which the first surface 1011 and the third surface 1021 face in opposite directions (e.g., in the case of an out-folding type).

In an embodiment, the electronic device 1001 may include a second display 1031 (e.g., an auxiliary display) disposed through the second surface 1012 of the first housing 1010, at least one second camera module 1008, and a flash 1009. For example, the second display 1031 may be disposed to be visible from the outside through at least a portion of the first rear cover 1014. In an embodiment, the electronic device 1001 may include a speaker 1002 disposed through the second side member 1040b, a microphone 1003 disposed through the first side member 1040a, and/or a connector port 1007. The arrangement of at least some of the components described above may be changed and/or modified between the first housing 1010 and/or the second housing 1020.

In an embodiment, at least one hinge device 1060, 1060-1 may be disposed at the bottom (e.g., the −Z direction of FIG. 10C) of the first display 1036 and may connect the first housing 1010 to the second housing 1020. For example, at least one hinge device 1060, 1060-1 may include a first hinge device 1060 disposed along the folding axis F and a second hinge device 1060-1 disposed to be spaced apart from the first hinge device 1060. In an embodiment, the first hinge device 1060 may be formed in a configuration that is substantially symmetrical or substantially identical to the second hinge device 1060-1. For example, at least one hinge device 1060, 1060-1 may be supported by a first support member 10131 extending from the first side member 1040a to a first space 10101 of the first housing 1010 and a second support member 10231 extending from the second side member 940b to a second space 10201 of the second housing 1020. In an embodiment, at least one hinge device 1060, 1060-1 may be covered by a hinge housing 1050 between the first housing 1010 and the second housing 1020 and may not be visible from the outside.

In an embodiment, the first hinge device 1060 may include a first rotating member 1064a (e.g., a first arm or a first rotator) disposed on the first support member 10131 of the first housing 1010, a second rotating member 1064b (e.g., a second arm or a second rotator) disposed on the second support member 10231 of the second housing 1020, and a gear assembly 1063 that connects the first rotating member 1064a to the second rotating member 1064b and symmetrically rotates the first housing 1010 and the second housing 1020 relative to each other. For example, the gear assembly 1063 may include a plurality of gears (e.g., spur gears and/or worm gears) that are gear-engaged with respect to one another. For example, the gear assembly may include a cam coupling structure and/or a spring structure for pressing the first housing 1010 and the second housing 1020 to transition in a direction from the first state to the second state or in a direction from the second state to the first state based on a predetermined angle relative to each other.

In an embodiment, the electronic device 1001 may be coupled with at least one hinge device 1060, 1060-1 and may include at least one detent module to provide a stopping sensation at various folding angles of the electronic device 1001. For example, at least one hinge device 1060, 1060-1 and/or detent module may form substantially the same plane as the first support member 10131 and the second support member 10231 when the electronic device 1001 is in the first state.

In an embodiment, the electronic device 1001 may further include at least one FPCB 10400 disposed in the electronic device 1001. In an embodiment, the FPCB 10400 may be disposed to extend from the first housing 1010 of the electronic device 1001 to the second housing 1020 across the folding axis F. In an embodiment, the FPCB 10400 may electrically connect a component element (e.g., a first PCB 1041) disposed in the first housing 1010 to a component element (e.g., a second PCB 1042) disposed in the second housing 1020. In an embodiment, the FPCB 10400 may be formed to be at least partially flexible and may at least partially bend to conform to a change in the shape of the electronic device 1001 when the electronic device 1001 changes between the first state and the second state.

Referring to FIGS. 10D and 10E, the FPCB 10400 according to an embodiment may be formed in a structure in which a plurality of layers overlap in the thickness direction T (e.g., Z-axis). In an embodiment, the FPCB 10400 may include a plurality of substrate layers 10410 sequentially disposed to overlap in the thickness direction T and a plurality of connecting layers 10420 disposed between the plurality of substrate layers 10410 and bonding at least a portion between adjacent substrate layers 10410. For example, the plurality of substrate layers 10410 may include a first substrate layer 10410a, a second substrate layer 10410b, and a third substrate layer 10410c. For example, the plurality of connecting layers 10420 may include at least one first connecting layer 10420a disposed between the first substrate layer 10410a and the second substrate layer 10410b and a second connecting layer 10420b disposed between the second substrate layer 10410b and the third substrate layer 10410c.

In an embodiment, a data line 10411-1 for transmitting a data signal, a power line 10411-2 for transmitting a power signal, and a ground line 10411-3 for grounding may be formed on the surface of each substrate layer 10410. In an embodiment, when the FPCB 10400 is viewed in the thickness direction (e.g., Z-axis), the FPCB 10400 may include a first circuit region 10510 in which the data line 10411-1 is positioned, a second circuit region 10520 in which the power line 10411-2 is positioned, and a third circuit region 10530a or 10530b in which the ground line 10411-3 is positioned.

In an embodiment, when the surface of the FPCB 10400 is viewed, the FPCB 10400 may be divided into at least one connecting region 10540 in which at least one pair of substrate layers 10410 are bonded with each other by the connecting layer 10420 and a non-connecting region 10550 in which the substrate layers 10410 are not bonded with one another. For example, it may be understood that the connecting layer 10420 is disposed in a part of the FPCB 10400 corresponding to the connecting region 10540. In an embodiment, the connecting region 10540 may be formed in a part that does not overlap the first circuit region 10510 of the FPCB 10400. For example, the connecting layer 10420 may be omitted from the surface of each substrate layer 10410 on which the data line 10411-1 is formed. In an embodiment, the connecting region 10540 may be formed in the second circuit region 10520 and/or the third circuit region 10530 of the FPCB 10400. In a part of the FPCB 10400 corresponding to the non-connecting region 10550, void spaces G may be formed between the substrate layers 10410.

In an embodiment, when the connecting region 10540 of the FPCB 10400 is formed in a part that does not overlap the first circuit region 10510, the phenomenon of deterioration in the transmission performance of a data signal through data lines 10411-1 of respective substrate layers 10410 of the FPCB 10400 may be reduced or prevented. At the same time, since the respective substrate layers 10410 of the FPCB 10400 are partially bonded through the connecting region 10540, when the FPCB 10400 bends according to the folding operation of the electronic device 1001, the phenomenon of gaps between the respective substrate layers 10410 becoming excessively wide may be reduced or prevented.

In an embodiment, the arrangement structure of the connecting region 10540 and the non-connecting region 10550 formed on the FPCB 10400 may be implemented through various embodiments of the FPCB illustrated in FIGS. 4A to 4J, 5A to 5C, 6A to 6C, 7A to 7E, and 8A to 8E described above.

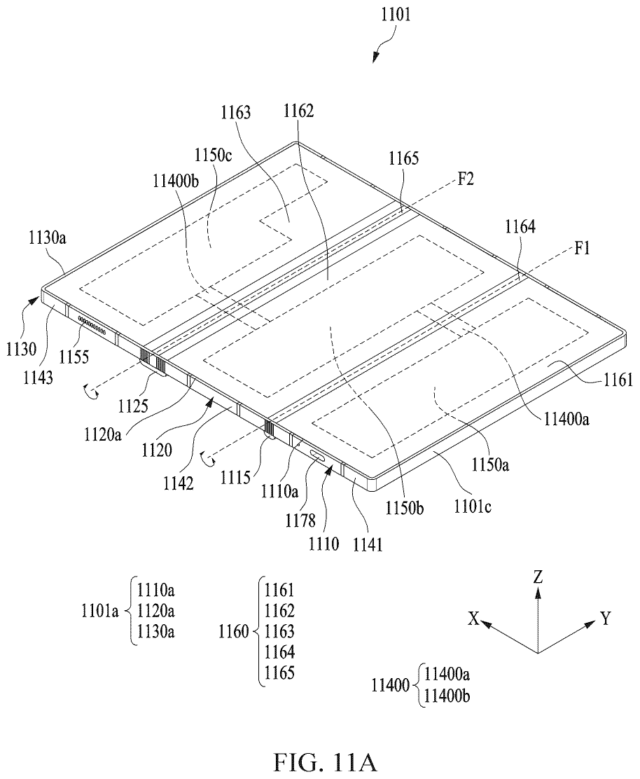

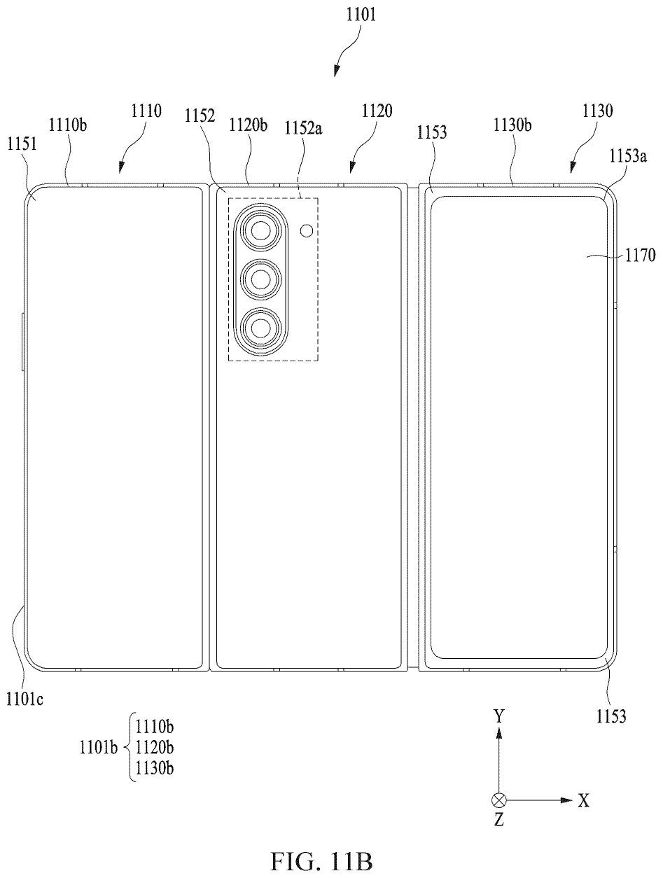

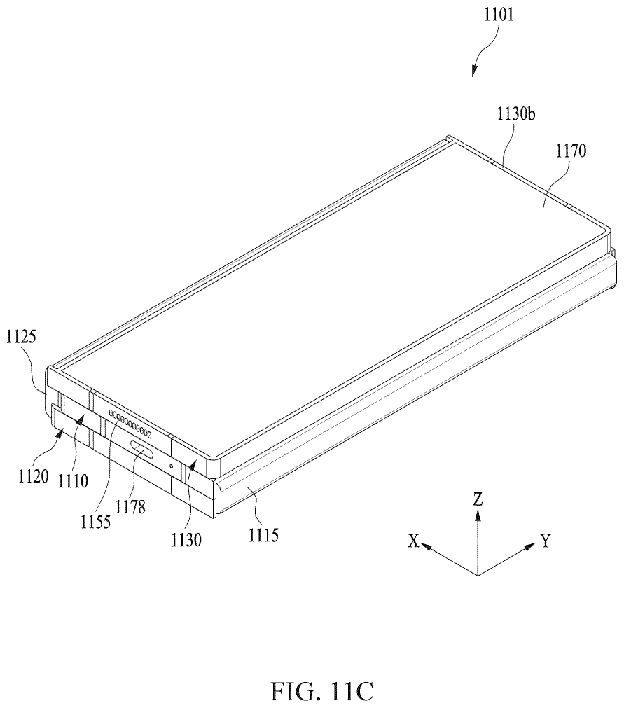

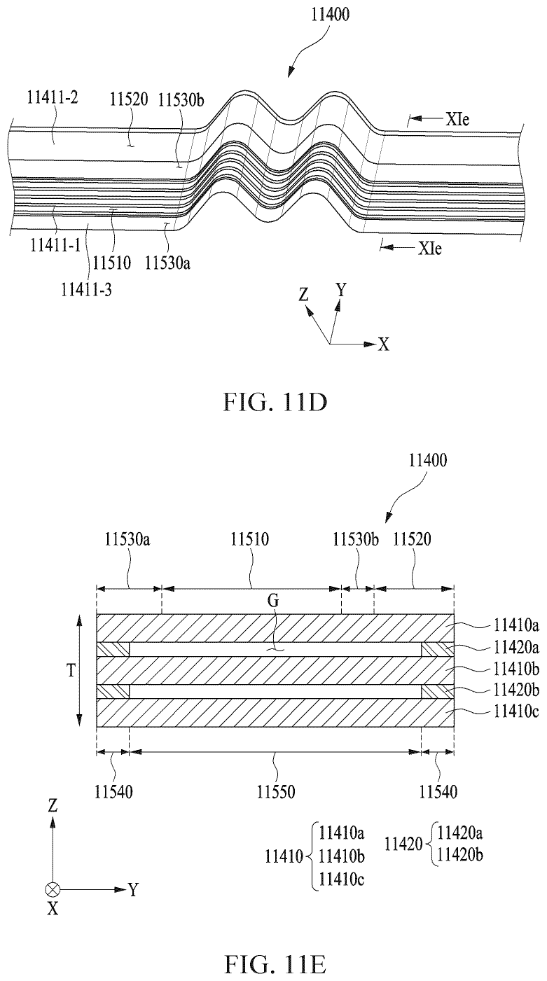

FIG. 11A is a perspective view illustrating a first state of an electronic device according to an embodiment of the disclosure.

FIG. 11B is a rear view illustrating the first state of the electronic device according to an embodiment of the disclosure.

FIG. 11C is a perspective view illustrating a second state of the electronic device according to an embodiment of the disclosure.

FIG. 11D is a partial perspective view of an FPCB according to an embodiment of the disclosure.

FIG. 11E is a cross-sectional view of the FPCB taken along the line XIe-XIe of FIG. 11D according to an embodiment of the disclosure.

Referring to FIGS. 11A to 11E, the shape of an electronic device 1101 (e.g., the electronic device 101 of FIG. 1) according to an embodiment may vary depending on a use state. For example, the electronic device 1101 may be provided in a foldable type that may be folded or unfolded according to the use state. In an embodiment, the electronic device 1101 may include a first housing 1110, a second housing 1120, a third housing 1130, a display 1160, a first hinge housing 1115, and a second hinge housing 1125.

Hereinafter, in describing FIGS. 11A to 11E, for ease of description, a surface of the display 1160 that is visually visible to the outside may be referred to as a front surface 1101a (e.g., a surface facing the +Z direction of FIG. 11A) of the electronic device 1101, a surface opposite to the front surface 1101a may be referred to as a rear surface 1101b (e.g., a surface facing the −Z direction of FIG. 10A) of the electronic device 1101, and an outer surface of the electronic device 1101 that surrounds an internal space between the front surface 1101a and the rear surface 1101b may be referred to as a side surface 1101c.

In an embodiment, the first housing 1110, the second housing 1120, and the third housing 1130 may form the exterior of the electronic device 1101. In an embodiment, the first housing 1110 may include a first front surface 1110a and a first rear surface 1110b. The second housing 1120 may include a second front surface 1120a and a second rear surface 1120b. The third housing 1130 may include a third front surface 1130a and a third rear surface 1130b. In an embodiment, the first front surface 1110a of the first housing 1110, the second front surface 1120a of the second housing 1120, and the third front surface 1130a of the third housing may form the front surface 1101a of the electronic device 1101 based on the unfolded state of the electronic device 1101 as illustrated in FIG. 11A. In an embodiment, most of the front surface 1101a of the electronic device 1101 may be open so that the display 1160 is visible to the outside. In an embodiment, the first rear surface 1110b of the first housing 1110, the second rear surface 1120b of the second housing 1120, and the third rear surface 1130b of the third housing may form the rear surface 1101b of the electronic device 1101 based on the unfolded state of the electronic device 1101 as illustrated in FIG. 11B. In an embodiment, the first housing 1110, the second housing 1120, and the third housing 1130 may each form the side surface 1101c surrounding an internal space between the front surface 1101a and the rear surface 1101b of the electronic device 1101.

In an embodiment, the first housing 1110 may include a first side member 1141 forming a portion of the side surface 1101c of the electronic device 1101. The first side member 1140a may include a conductive portion. In an embodiment, the second housing 1120 may include a second side member 1142 forming a portion of the side surface 1101c of the electronic device 1101. The second side member 1142 may include a conductive portion. In an embodiment, the third housing 1130 may include a third side member 1143 forming a portion of the side surface 1101c of the electronic device 1101. The third side member 1143 may include a conductive portion.

In an embodiment, a first rear cover 1151 may be disposed on the first rear surface 1110b of the first housing 1110. At least a portion of the edge of the first rear cover 1151 may be surrounded by the first housing 1110. In an embodiment, a second rear cover 1152 may be disposed on the second rear surface 1120b of the second housing 1120. At least a portion of the edge of the second rear cover 1152 may be surrounded by the second housing 1120. In an embodiment, a third rear cover 1153 may be disposed on the third rear surface 1130b of the third housing 1130. At least a portion of the edge of the third rear cover 1153 may be surrounded by the third housing 1130. In an embodiment, the first rear cover 1151, the second rear cover 1152, and the third rear cover 1153 may be formed integrally with the first housing 1110, the second housing 1120, and the third housing 1130, respectively.

In an embodiment, the first housing 1110, the second housing 1120, the third housing 1130, the first rear cover 1151, the second rear cover 1152, and the third rear cover 1153 may be coupled to one another to form a space in which various components (e.g., circuit boards 1150a, 1150b, and 1150c of FIG. 11A) of the electronic device 1101 may be disposed. In an embodiment, at least one component may be disposed to be visible on the rear surface 1101b of the electronic device 1101. For example, at least one component (e.g., a proximity sensor, a rear camera module, and/or a flash) may be visible to the outside through a second rear region 1152a of the second rear cover 1152. In an embodiment, at least a portion of a sub-display 1170 may be visually exposed through a third rear region 1153a of the third rear cover 1153.

In an embodiment, the first hinge housing 1115 may rotatably connect the first housing 1110 to the second housing 1120 about a first folding axis F1. In an embodiment, the second hinge housing 1125 may rotatably connect the second housing 1120 to the third housing 1130 about a second folding axis F2. In an embodiment, the first folding axis F1 and the second folding axis F2 may be parallel to each other.

In an embodiment, the shape of at least a portion of the display 1160 may change such that the shape of the display 1160 may change in response to an opening/closing operation of the electronic device 1101 between changes (e.g., the first state (e.g., unfolded state or fully open state) of FIG. 11A and the second state (e.g., folded state or fully closed state) of FIG. 11C) in shape of the electronic device 1101. In an embodiment, the display 1160 may be supported by the first housing 1110, the second housing 1120, the third housing 1130, the first hinge housing 1115, and the second hinge housing 1125 and may be disposed to be visible to the outside through the front surface 1101a of the electronic device 1101.

In an embodiment, the display 1160 may include a first flat portion 1161 corresponding to the first housing 1110, a second flat portion 1162 corresponding to the second housing 1120, a third flat portion 1163 corresponding to the third housing 1130, a first folding portion 1164 connecting the first flat portion 1161 to the second flat portion 1162 and corresponding to the first hinge housing 1115, and a second folding portion 1165 connecting the second flat portion 1162 to the third flat portion 1163 and corresponding to the second hinge housing 1125. In an embodiment, the first folding portion 1164 and the second folding portion 1165 may at least partially bend to conform to a change in shape of the electronic device 1101.

In an embodiment, the electronic device 1101 may include a connector port 1178 (e.g., the connecting terminal 178 of FIG. 1) disposed through the side surface 1101c and an audio output module 1155 including one or more holes formed in the side surface 1101c.

In an embodiment, the electronic device 1101 may include a plurality of FPCBs 11400 disposed therein. In an embodiment, the plurality of FPCBs 11400 may include a first FPCB 11400a disposed to extend from the first housing 1110 to the second housing 1120 across the first folding axis F1 and a second FPCB 11400b disposed to extend from the second housing 1120 to the third housing 1130 across the second folding axis F2. In an embodiment, the first FPCB 11400a may electrically connect a component element (e.g., the first PCB 1150a) disposed in the first housing 1110 to a component element (e.g., the second PCB 1150b) disposed in the second housing 1120. In an embodiment, the second FPCB 11400b may electrically connect a component element (e.g., the second PCB 1150b) disposed in the second housing 1120 to a component element (e.g., the third PCB 1150c) disposed in the third housing 1130. In an embodiment, each FPCB 11400 may be formed to be at least partially flexible and may at least partially bend to conform to changes in the shape of the electronic device 1101.

Referring to FIGS. 11D and 11E, the FPCB 11400 according to an embodiment may be formed in a structure in which a plurality of layers overlap in the thickness direction T (e.g., Z-axis). In an embodiment, the FPCB 11400 may include a plurality of substrate layers 11410 sequentially disposed to overlap in the thickness direction T and a plurality of connecting layers 11420 disposed between the plurality of substrate layers 11410 and bonding at least a portion between adjacent substrate layers 11410. For example, the plurality of substrate layers 11410 may include a first substrate layer 11410a, a second substrate layer 11410b, and a third substrate layer 11410c. For example, the plurality of connecting layers 11420 may include at least one first connecting layer 11420a disposed between the first substrate layer 11410a and the second substrate layer 11410b and a second connecting layer 11420b disposed between the second substrate layer 11410b and the third substrate layer 11410c.

In an embodiment, a data line 11411-1 for transmitting a data signal, a power line 11411-2 for transmitting a power signal, and a ground line 11411-3 for grounding may be formed on the surface of each substrate layer 11410. In an embodiment, when the FPCB 11400 is viewed in the thickness direction (e.g., Z-axis), the FPCB 11400 may include a first circuit region 11510 in which the data line 11411-1 is positioned, a second circuit region 11520 in which the power line 11411-2 is positioned, and a third circuit region 11530a or 11530b in which the ground line 11411-3 is positioned.

In an embodiment, when the surface of the FPCB 11400 is viewed, the FPCB 11400 may be divided into at least one connecting region 11540 in which at least one pair of substrate layers 11410 are bonded with each other by the connecting layer 11420 and a non-connecting region 11550 in which the substrate layers 11410 are not bonded with one another. For example, it may be understood that the connecting layer 11420 is disposed in a part of the FPCB 11400 corresponding to the connecting region 11540. In an embodiment, the connecting region 11540 may be formed in a part that does not overlap the first circuit region 11510 of the FPCB 11400. For example, the connecting layer 11420 may be omitted from the surface of each substrate layer 11410 on which the data line 11411-1 is formed. In an embodiment, the connecting region 11540 may be formed in the second circuit region 11520 and/or the third circuit region 11530 of the FPCB 11400. In a part of the FPCB 11400 corresponding to the non-connecting region 11550, void spaces G may be formed between the substrate layers 11410.

In an embodiment, when the connecting region 11540 of the FPCB 11400 is formed in a portion that does not overlap the first circuit region 11510, the phenomenon of deterioration in the transmission performance of a data signal through data lines 11411-1 of respective substrate layers 11410 of the FPCB 11400 may be reduced or prevented. At the same time, since the respective substrate layers 11410 of the FPCB 11400 are partially bonded through the connecting region 11540, when the FPCB 11400 bends according to the folding operation of the electronic device 1101, the phenomenon of gaps between the respective substrate layers 11410 becoming excessively wide may be reduced or prevented.

In an embodiment, the arrangement structure of the connecting region 11540 and the non-connecting region 11550 formed on the FPCB 11400 may be implemented through various embodiments of the FPCB illustrated in FIGS. 4A to 4J, 5A to 5C, 6A to 6C, 7A to 7E, and 8A to 8E described above.

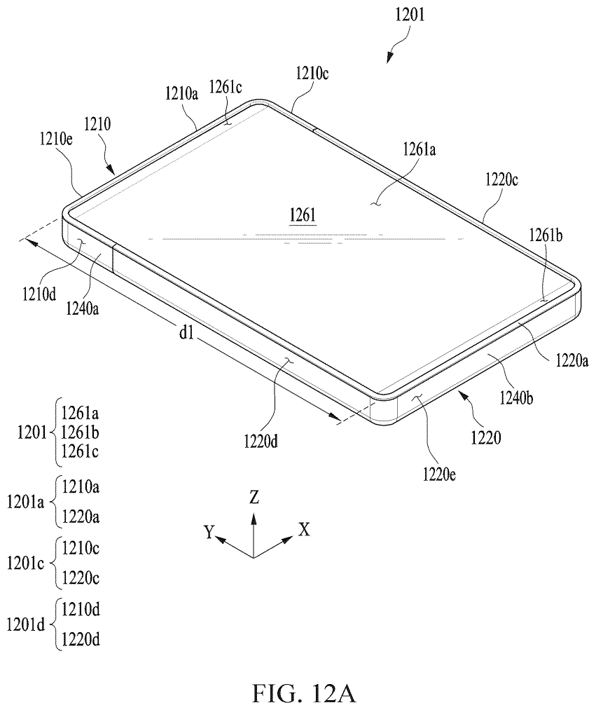

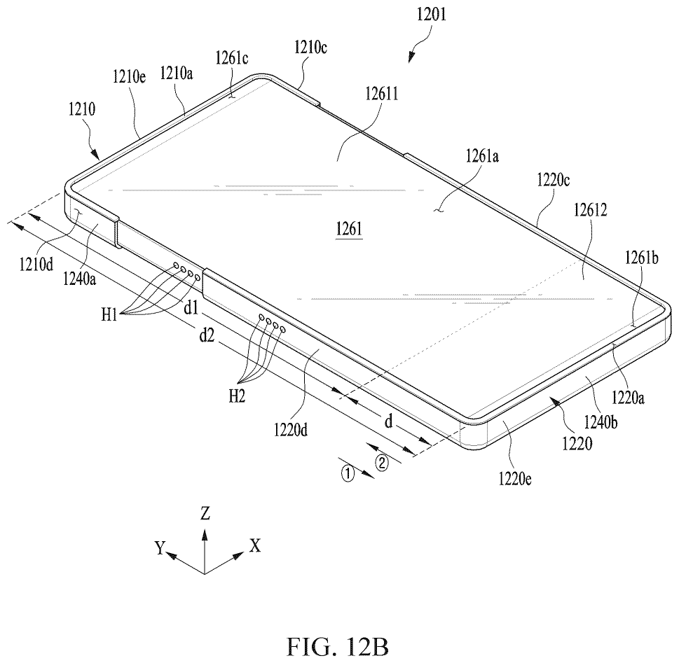

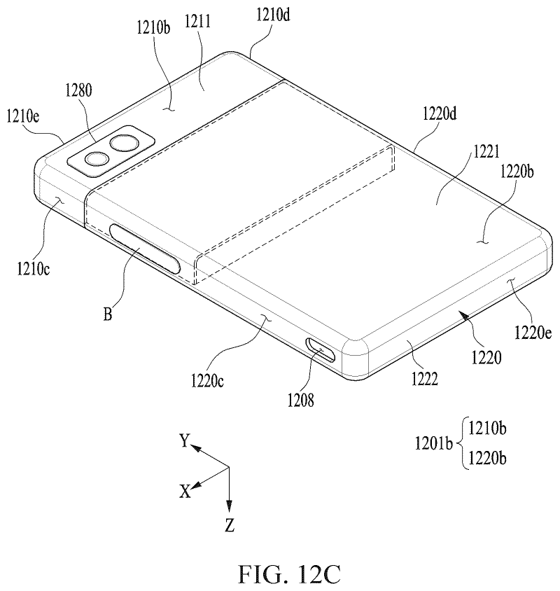

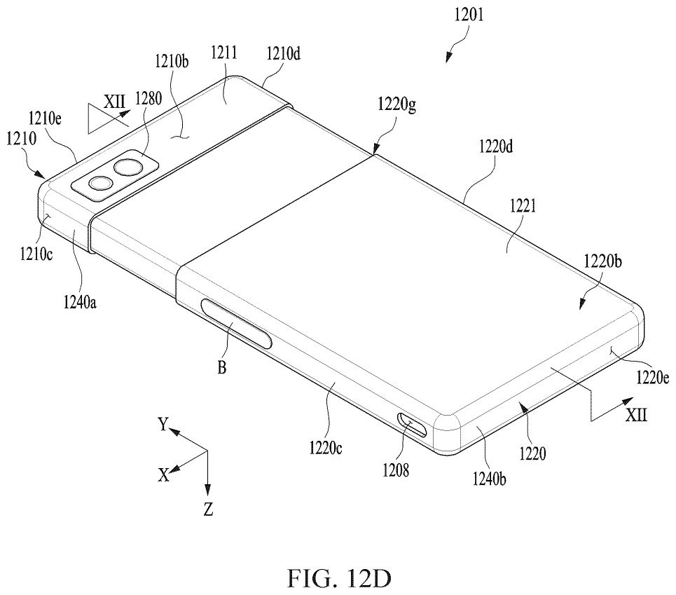

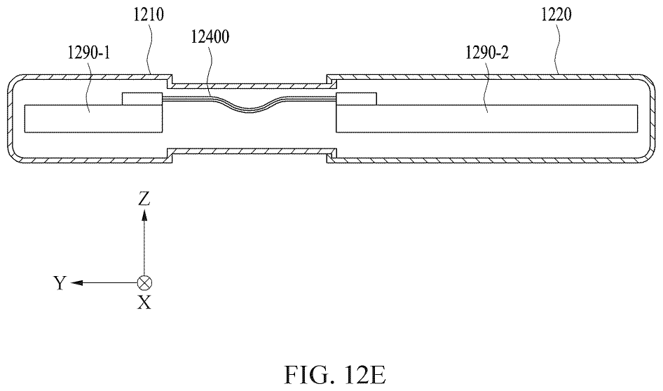

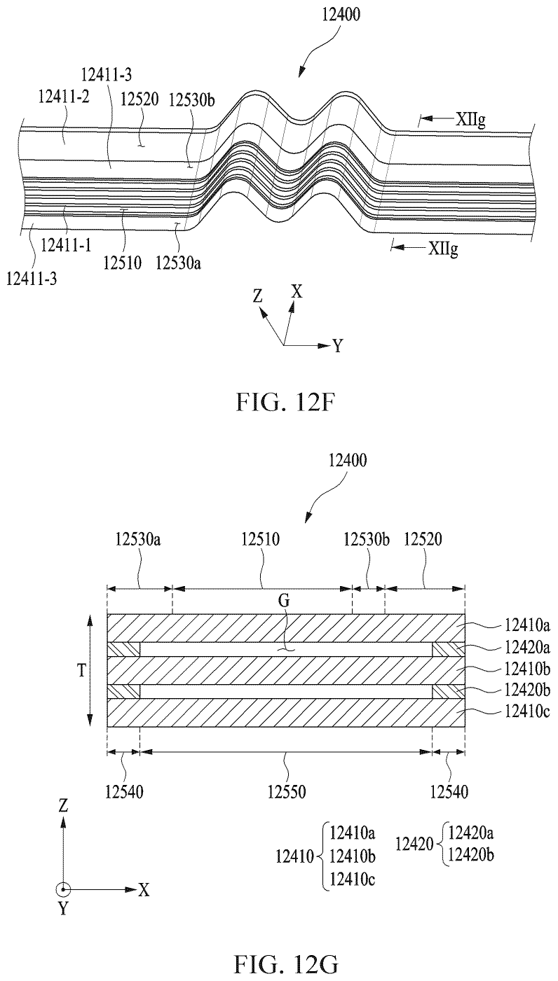

FIG. 12A is a front perspective view illustrating a first state of an electronic device according to an embodiment of the disclosure.

FIG. 12B is a front perspective view illustrating a second state of the electronic device according to an embodiment of the disclosure.

FIG. 12C is a rear perspective view illustrating the first state of the electronic device according to an embodiment of the disclosure.

FIG. 12D is a rear perspective view illustrating the second state of the electronic device according to an embodiment of the disclosure.

FIG. 12E is a side perspective view of the electronic device illustrating an FPCB according to an embodiment of the disclosure.

FIG. 12F is a partial perspective view of the FPCB according to an embodiment of the disclosure.

FIG. 12G is a cross-sectional view of the FPCB taken along the line XIIg-XIIg of FIG. 12F according to an embodiment of the disclosure.

Referring to FIGS. 12A, 12B, 12C, 12D, and 12E, an electronic device 1201 (e.g., the electronic device 101 of FIG. 1) according to an embodiment may have a deformable shape. In an embodiment, the size of the electronic device 1201 may change by expanding and contracting along a moving direction (e.g., a direction parallel to the Y-axis of FIG. 12A). For example, the electronic device 1201 may be transformed between a first state (e.g., a slide-in state) as illustrated in FIG. 12A and a second state (e.g., a slide-out state) as illustrated in FIG. 12B.

In an embodiment, the electronic device 1201 may include housings 1210 and 1220 that form an exterior and accommodate components therein. In an embodiment, the housings 1210 and 2820 may include a first housing 1210 and a second housing 1220 that are movably connected to each other. In an embodiment, the first housing 1210 may be slidably connected to the second housing 1220. For example, the first housing 1210 may move in a first moving direction \textcircled{1} (e.g., −Y direction) relative to the second housing 1220 or may slide in a second moving direction \textcircled{2} (e.g., +Y direction) opposite to the first moving direction \textcircled{1} Hereinafter, the state transformation of the electronic device 1201 illustrated in FIGS. 12A to 12D is described based on the slide in/out operation of the first housing 1210 with respect to the second housing 1220, but this is for describing the relative moving operation between the first housing 1210 and the second housing 1220 and may be understood as the second housing 1220 moving with respect to the first housing 1210.

In an embodiment, depending on the relative movement of the second housing 1220 with respect to the first housing 1210, the state of the electronic device 1201 may change between a first state (e.g., a slide-in state) and a second state (e.g., a slide-out state). In an embodiment, the electronic device 1201 may have a minimum exposure region of a display 1261 in the first state and may have a maximum exposure region of the display 1261 in the second state. In an embodiment, the electronic device 1201 may be used in the first state and the second state and may also be used in an intermediate state between the first state and the second state.

In an embodiment, the first housing 1210 may include a (1-1)-th surface 1210a (e.g., a first front surface), a (1-2)-th surface 1210b (e.g., a first rear surface) opposite to the (1-1)-th surface 1210a, a (1-1)-th side surface 1210c facing a first lateral direction (e.g., +X direction) and formed between the (1-1)-th surface 1210a and the (1-2)-th surface 1210b, a (1-2)-th side surface 1210d facing a second lateral direction (e.g., −X direction) opposite to the first lateral direction and formed between the (1-1)-th surface 1210a and the (1-2)-th surface 1210b, and a third side surface 1210e facing a third lateral direction (e.g., +Y direction) intersecting with the first lateral direction and formed between the (1-1)-th surface 1210a and the (1-2)-th surface 1210b.

In an embodiment, the first housing 1210 may include a first plate 1211 and a first side member 1240a extending substantially in the thickness direction (e.g., +Z direction) along the edge of the first plate 1211. In an embodiment, the first plate 1211 may form the (1-2)-th side 1210b, and the first side member 1240a may form the side surfaces 1210c, 1210d, and 1210e of the first housing 1210. In an embodiment, the first plate 1211 and the first side member 1240a may be integrally formed or separately formed to be coupled to each other. In an embodiment, the first side member 1240a may include a conductive portion.

In an embodiment, the second housing 1220 may include a (2-1)-th surface 1220a (e.g., a second front surface), a (2-2)-th surface 1220b (e.g., a second rear surface) opposite to the (2-1)-th surface 1220a, a (2-1)-th side surface 1220c facing a first lateral direction (e.g., +X direction) and formed between the (2-1)-th surface 1220a and the (2-2)-th surface 1220b, a (2-2)-th side surface 1220d facing a second lateral direction (e.g., −X direction) opposite to the first lateral direction and formed between the (2-1)-th surface 1220a and the (2-2)-th surface 1220b, and a fourth side surface 1220e facing a fourth lateral direction (e.g., −Y direction) intersecting with the first lateral direction and formed between the (2-1)-th surface 1220a and the (2-2)-th surface 1220b.

In an embodiment, the second housing 1220 may include a second plate 1221 and a second side member 1240b extending substantially in the thickness direction (e.g., +Z direction) along the edge of the second plate 1221. In an embodiment, the second plate 1221 may form the (2-2)-th surface 1220b, and the second side member 1240b may form the side surfaces 1220c, 1220d, and 1220e of the second housing 1220. In an embodiment, the second plate 1221 and the second side member 1240b may be integrally formed or separately formed to be coupled to each other. In an embodiment, the second side member 1240b may include a conductive portion.

In an embodiment, the first housing 1210 and the second housing 1220 may form a first surface (front surface) 1201a (e.g., a surface facing +Z) of the electronic device 1201 through the (1-1)-th surface 1210a and the (2-1)-th surface 1220a and may form a second surface (rear surface) 1201b (e.g., a surface facing −Z) of the electronic device 1201 through the (1-2)-th surface 1210b and the (2-2)-th surface 1220b. In an embodiment, the first surface 1201a of the electronic device 1201 may be open to expose the display 1261. In an embodiment, the first housing 1210 and the second housing 1220 may form a first side surface 1201c (e.g., a surface facing +X) of the electronic device 1201 through the (1-1)-th side surface 1210c and the (2-1)-th side surface 1220c and may form a second side surface 1201d (e.g., a surface facing-X) of the electronic device 1201 through the (1-2)-th side surface 1210d and the (2-2)-th side surface 1220d.

In an embodiment, the first housing 1210 may be withdrawn from or inserted into the second housing 1220 while being partially inserted into the second housing 1220. In an embodiment, the second housing 1220 may include an open portion 1220g that is formed to open in a fourth lateral direction (e.g., +Y direction) opposite to the third lateral direction so that the first housing 1210 may be inserted thereto. In an embodiment, during the process of introducing the first housing 1210 into the second housing 1220, at least a portion of the (1-1)-th side surface 1210c and the (1-2)-th side surface 1210d of the first housing 1210 may be inserted into the second housing 1220 and covered by the (2-1)-th side surface 1220c and the (2-2)-th side surface 1220d. Accordingly, the first side surface 1201c and the second side surface 1201d of the electronic device 1201 may change in length depending on the state of the electronic device 1201.

In an embodiment, the electronic device 1201 may include the display 1261 (e.g., a flexible display or a rollable display) for displaying visual information. In an embodiment, the display 1261 may be exposed to the outside, for example, the front, of the electronic device 1201 through a display region. In an embodiment, the display region may include a first region 1261a positioned on the (1-1)-th surface 1210a and the (2-1)-th surface 1220a, a second region 1261b positioned adjacent to the fourth side surface 1220e, and a third region 1261c positioned adjacent to the third side surface 1210e. In an embodiment, the second region 1261b and/or the third region 1261c may form a flexibly curved surface. In an embodiment, the display region of the display 1261 may be expanded or reduced according to a change in the size of the first region 1261a. In an embodiment, the display 1261 may display a screen in the display region. In an embodiment, the display 1261 may display a single connected screen through the display region or may display a screen using only a portion of the display region. In an embodiment, the display 1261 may display a plurality of screens separated on the display region.

In an embodiment, the display 1261 may form at least a portion (e.g., the first region 1261a in the first state of FIG. 12A) of the display region and may include a flat portion 12611 supported by the first housing 1210 and the second housing 1220 and a rolling portion 12612 (or a bending portion) extending in the first moving direction from the flat portion 12611 and supported by the second housing 1220. In an embodiment, the flat portion 12611 may be visually exposed to the first surface 1201a of the housings 1210 and 1220 to form a display region regardless of the state change of the electronic device 1201. In an embodiment, the rolling portion 12612 may be inserted into the electronic device 1201 or withdrawn to the outside of the electronic device 1201 depending on the moving operation of the first housing 1210 relative to the second housing 1220. In an embodiment, the rolling portion 12612 withdrawn to the outside of the electronic device 1201 may be disposed on the (2-1)-th surface 1220a of the second housing 1220 to be visually exposed to the outside of the electronic device 1201 and form a display region together with the flat portion 12611. For example, the area of the display region may change according to the degree of withdrawal of the rolling portion 12612.

In an embodiment, the area of the display region (e.g., the first region 1261a, the second region 1261b, and the third region 1261c) of the display 1261 may change in response to a change in the state of the electronic device 1201. In an embodiment, the display region of the display 1261 may form a first area (e.g., a minimum area) that is minimized in the first state (e.g., the slide-in state of FIG. 12A) of the electronic device 1201 and a second area (e.g., a maximum area) that is maximized in the second state (e.g., the slide-out state of FIG. 12B) of the electronic device 1201. When the electronic device 1201 is in a state between the first state and the second state, the state of the display 1261 may change in response to the state of the electronic device 1201, thereby causing the display region to have an area between the first area and the second area. For example, in an operation in which the state of the electronic device 1201 changes from the first state to the second state, when the first housing 1210 moves in the second moving direction \textcircled{2} with respect to the second housing 1220 by a predetermined length d, the length (e.g., the length parallel to the Y-axis) of the display region parallel to the second moving direction \textcircled{2} may change to a second length d2 that increases from a first length d1 by the predetermined length d, thereby expanding the display region. For example, when the state of the electronic device 1201 changes from the second state to the first state, as the first housing 1210 moves in the first moving direction \textcircled{1} with respect to the second housing 1220 by the predetermined length d, the length (e.g., the length parallel to the Y-axis) of a display region parallel to the first moving direction \textcircled{1} may change to the first length d1 that is reduced from the second length d2 by the predetermined length d, thereby reducing the display region. In an embodiment, the sizes of the second region 1261b and the third region 1261c may be maintained substantially constant regardless of the change in the state of the electronic device 1201.

In an embodiment, the electronic device 1201 may include an input button B (e.g., the input module 150 of FIG. 1), an audio output module (e.g., the sound output module 155 of FIG. 1), a camera module 1280 (e.g., the camera module 180 of FIG. 1), and a connector port 1208. In an embodiment, the electronic device 1201 may omit at least one of the components described above or may additionally include other components.

In an embodiment, the input button B may receive an input signal according to the manipulation of a user. The input button B may be disposed outside the electronic device 1201 and pressed by the user to transmit the input signal to a processor (e.g., the processor 120 of FIG. 1). In an embodiment, the input button B may be formed on the side surfaces of the housings 1210 and 1220. For example, the input button B may be formed on at least one of the (2-3)-th side surface 1220c or the (2-4)-th side surface 1220d of the second housing 1220. In the diagram, for ease of description, an embodiment is illustrated in which one input button B is formed on the (2-3)-th side surface 1220c of the second housing 1220. However, the arrangement position and the number of input buttons B for the electronic device 1201 illustrated in the diagram are for ease of description and are not limited to the illustrated embodiment.

In an embodiment, a sound output module may be radiated externally through sound holes H1 and H2 communicating with the outside of the housings 1210 and 1220. In an embodiment, the sound holes H and H2 may include, for example, a first sound hole H1 formed in the first housing 1210 and a second sound hole H2 formed in the second housing 1220. In an embodiment, the first sound hole H1 and the second sound hole H2 may be substantially aligned to be in communication with each other in the first state of the electronic device 1201.

In an embodiment, the electronic device 1201 may include an FPCB 12400 disposed therein. In an embodiment, the FPCB 12400 may be disposed to extend from the inside of the first housing 1210 to the inside of the second housing 1220. In an embodiment, the FPCB 12400 may electrically connect a first component element (e.g., a first PCB 1290-1) disposed in the first housing 1210 and a second component element (e.g., a second PCB 1290-2) disposed in the second housing 1220. In an embodiment, the FPCB 12400 may at least partially bend in response to a state change of the electronic device 1101, such as a sliding operation of the second housing 1220 relative to the first housing 1210.

Referring to FIGS. 12F and 12G, the FPCB 12400 according to an embodiment may be formed in a structure in which a plurality of layers overlap in the thickness direction T (e.g., Z-axis). In an embodiment, the FPCB 12400 may include a plurality of substrate layers 12410 sequentially disposed to overlap in the thickness direction T and a plurality of connecting layers 12420 disposed between the plurality of substrate layers 12410 and bond at least a portion between adjacent substrate layers 12410. For example, the plurality of substrate layers 12410 may include a first substrate layer 12410a, a second substrate layer 12410b, and a third substrate layer 12410c. For example, the plurality of connecting layers 12420 may include at least one first connecting layer 12420a disposed between the first substrate layer 12410a and the second substrate layer 12410b and a second connecting layer 12420b disposed between the second substrate layer 12410b and the third substrate layer 12410c.

In an embodiment, a data line 12411-1 for transmitting a data signal, a power line 12411-2 for transmitting a power signal, and a ground line 12411-3 for grounding may be formed on the surface of each substrate layer 12410. In an embodiment, when the FPCB 12400 is viewed in the thickness direction (e.g., Z-axis), the FPCB 12400 may include a first circuit region 12510 in which the data line 12411-1 is positioned, a second circuit region 12520 in which the power line 12411-2 is positioned, and a third circuit region 12530a or 12530b in which the ground line 12411-3 is positioned.

In an embodiment, when the surface of the FPCB 12400 is viewed, the FPCB 12400 may be divided into at least one connecting region 12540 in which at least one pair of substrate layers 12410 are bonded with each other by the connecting layer 12420 and a non-connecting region 12550 in which the substrate layers 12410 are not bonded with one another. For example, it may be understood that the connecting layer 12420 is disposed in a part of the FPCB 12400 corresponding to the connecting region 12540. In an embodiment, the connecting region 12540 may be formed in a part that does not overlap the first circuit region 12510 of the FPCB 12400. For example, the connecting layer 12420 may be omitted from the surface of each substrate layer 12410 on which the data line 12411-1 is formed. In an embodiment, the connecting region 12540 may be formed in the second circuit region 12520 and/or the third circuit region 12530 of the FPCB 12400. In a part of the FPCB 12400 corresponding to the non-connecting region 12550, void spaces G may be formed between the substrate layers 12410.

In an embodiment, when the connecting region 12540 of the FPCB 12400 is formed in a part that does not overlap the first circuit region 12510, the phenomenon of deterioration in the transmission performance of a data signal through data lines 12411-1 of respective substrate layers 12410 of the FPCB 12400 may be reduced or prevented. For example, as the respective substrate layers 12410 of the FPCB 12400 are partially bonded with one another through the connecting region 12540, when the FPCB 12400 is partially unfolded or folded according to a change in the state of the electronic device 1201, for example, insertion and withdrawal operations of the first housing 1210 into and from the second housing 1220, the phenomenon of gaps between the respective substrate layers 12410 becoming excessively wide may be reduced or prevented.

In an embodiment, the arrangement structure of the connecting region 12540 and the non-connecting region 12550 formed on the FPCB 12400 may be implemented through various embodiments of the FPCB illustrated in FIGS. 4A to 4J, 5A to 5C, 6A to 6C, 7A to 7E, and 8A to 8E described above.

The technical goals to be achieved are not limited to those described above, and other technical goals not mentioned above are clearly understood by one of ordinary skill in the art to which the disclosure pertains.

A wearable electronic device 101, 201, 301, 401, or 801 according to an embodiment may include a frame 4100 or 8100 configured to accommodate at least one lens or at least one display, a temple 4200 or 8200 connected to each of both ends of the frame 4100 or 8100, and an FPCB 4400, 5400A, 6400, 7400, or 8400 of which at least a portion is disposed in the temple 4200 or 8200 and extending in a longitudinal direction. In an embodiment, the FPCB 4400, 5400A, 6400, 7400, or 8400 may include a plurality of substrate layers 4410, 5410, 6410, 7410, and 8410 including at least one circuit line 4411 formed on a surface thereof and disposed to overlap in a thickness direction T and at least one connecting layer 4420, 5420, 6420, 7420, or 8420 disposed between the plurality of substrate layers 4410, 5410, 6410, 7410, or 8410 and configured to connect surfaces of adjacent substrate layers 4410, 5410, 6410, 7410, or 8410. In an embodiment, the FPCB 4400, 5400A, 6400, 7400, or 8400, when viewed in the thickness direction T, may include a first circuit region 4510, 5510, 6510, 7510, or 8510 in which a data line 4411-1, 5411-1, 6411-1, 7411-1, or 8411-1 for transmitting a data signal is formed, and the connecting layer 4420, 5420, 6420, 7420, or 8420 is disposed not to overlap the first circuit region.

In an embodiment, the FPCB 4400, 5400, 6400, 7400, or 8400 may further include a second circuit region 4520, 5520, 6520, 7520, or 8520 not overlapping the first circuit region 4510, 5510, 6510, 7510, or 8510 and including a power line 4411-2, 5411-2, 6411-2, 7411-2, or 8411-2 or transmitting a power signal. When the FPCB 4400, 5400, 6400, 7400, or 8400 is viewed in the thickness direction T, the connecting layer 4420, 5420, 6420, 7420, or 8420 may overlap the second circuit region 4520, 5520, 6520, 7520, or 8520.

In an embodiment, the connecting layer 7420 may be disposed to overlap an entirety of the second circuit region 7520.

In an embodiment, the FPCB 4400, 5400A, 6400, 7400, or 8400 may further include a third circuit region 4530, 5530, 6530, 7530, or 8530 including a ground line 4411-3, 5411-3, 6411-3, 7411-3, or 8411-3. When the FPCB 4400, 5400A, 6400, 7400, or 8400 is viewed in the thickness direction T, the connecting layer 4420, 5420, 6420, 7420, or 8420 may overlap the third circuit region 4530, 5530, 6530, 7530, or 8530.

In an embodiment, each of the plurality of substrate layers 8410 may include at least one protruding portion 8412 protruding outward in the width direction perpendicular to the longitudinal direction. When the FPCB 8400 is viewed in the thickness direction T, the connecting layer 8420 may overlap the at least one protruding portion 8412.

In an embodiment, the at least one protruding portion 8412 may include at least one guide hole 8412a formed through the at least one protruding portion 8412 in the thickness direction T.

In an embodiment, the FPCB 8400D may be formed on the at least one protruding portion 8412 and include at least one via hole 8412b connected to ground.

In an embodiment, the FPCB 4400, 5400A, or 5400B may include at least one bending portion 4430 or 5430 at least partially bending in the thickness direction T. The connecting layer 5420 may be disposed not to overlap the bending portion 5430.

In an embodiment, when viewed in the thickness direction T, the FPCB 4400, 5400A, 6400, 7400, or 8400 may include at least one connecting region 4540, 5540, 6540, 7540, or 8540 in which the connecting layer 4420, 5420, 6420, 7420, or 8420 is positioned. The connecting region 5540 may be disposed to be adjacent to the bending portion 5430.

In an embodiment, on the FPCB 5400A or 5400B, the connecting region 5540 may be positioned at each of both ends in the longitudinal direction of the bending portion 5430.

In an embodiment, the FPCB 5400C may include at least one bending portion 5430 at least partially bending in the thickness direction T. The connecting region 5540 may include a first connecting region 5540A and/or a second connection region 5540B in which the connecting layer 5420 is disposed not to overlap the bending portion 5430 and a third connecting region 5540C in which the connecting layer 5420 is disposed to overlap the bending portion. The third connecting region 5540C may have a thinner thickness than the first connecting region 5540A and/or the second connection region 5540B.

In an embodiment, in at least one connecting region 5540 disposed to be adjacent to the bending portion 5430, at least one pair of connecting layers 5420a or 5420b disposed between different substrate layers 5410 may have different areas.

In an embodiment, based on a cross-section of the FPCB 4400, 5400, 6400, 7400, or 8400, the connecting layer 4420, 5420, 6420, 7420, or 8420 may be disposed at each of both ends in the width direction of the FPCB 4400, 5400, 6400, 7400, or 8400.

In an embodiment, at least a part of the FPCB 4400 may be disposed in a part in which the temple 4200 is connected to the frame 4100. The connecting layer 4420 may be disposed in at least a part of a part of the FPCB 4400 disposed in the part in which the temple 4200 is connected to the frame 4100.

In an embodiment, the plurality of substrate layers 4410, 5410, 6410, 7410, or 8410 may include a first substrate layer 4410a, 5410a, 6410a, 7410a, or 8410a, a second substrate layer 4410b, 5410b, 6410b, 7410b, or 8410b, and a third substrate layer 4410c, 5410c, 6410c, 7410c, or 8410c. The connecting layer 4420, 5420, 6420, 7420, or 8420 may include at least one first connecting layer 4420a, 5420a, 6420a, 7420a, or 8420a disposed on at least a portion between the first substrate layer 4410a, 5410a, 6410a, 7410a, or 8410a and the second substrate layer 4410b, 5410b, 6410b, 7410b, or 8410b and at least one second connecting layer 4420b, 5420b, 6420b, 7420b, or 8420b disposed on at least a portion between the second substrate layer 4410b, 5410b, 6410b, 7410b, or 8410b and the third substrate layer 4410c, 5410c, 6410c, 7410c, or 8410c.

When viewed in the thickness direction, the first connecting layer 4420a, 5420a, 6420a, 7420a, or 8420a at least partially overlaps the second connecting layer 4420b, 5420b, 6420b, 7420b, or 8420b.

An FPCB 4400, 5400A, 6400, 7400, 8400, 9400, 10400, 11400, or 12400 according to an embodiment may include a plurality of substrate layers 4410, 5410, 6410, 7410, 8410, 9410, 10410, 11410, and 12410 including a circuit line 4411 formed on surfaces thereof and disposed to overlap in a thickness direction T and at least one connecting layer 4420, 5420, 6420, 7420, 8420, 9420, 10420, 11420, or 12420 configured to connect at least a portion of the plurality of substrate layers 4410, 5410, 6410, 7410, 8410, 9410, 10410, 11410, and 12410. Each of the plurality of substrate layers 4410, 5410, 6410, 7410, 8410, 9410, 10410, 11410, and 12410 may include a first circuit region 4510, 5510, 6510, 7510, 8510, 9510, 10510, 11510, or 12510 including a data line 4411-1, 5411-1, 6411-1, 7411-1, 8411-1, 9411-1, 10411-1, 11411-1, or 12411-1 for transmitting a data signal in the longitudinal direction of the FPCB 4400, 5400A, 6400, 7400, 8400, 9400, 10400, 11400, or 12400 and a second circuit region 4520, 5520, 6520, 7520, 8520, 9520, 10520, 11520, or 12520 including a power line 4411-2, 5411-2, 6411-2, 7411-2, 8411-2, 9411-2, 10411-2, 11411-2, or 12411-2 for transmitting a power signal in the longitudinal direction of the FPCB. The connecting layer 4420, 5420, 6420, 7420, 8420, 9420, 10420, 11420, or 12420 may be disposed not to overlap the first circuit region 4510, 5510, 6510, 7510, 8510, 9510, 10510, 11510, or 12510.

In an embodiment, the connecting layer 7420 may be disposed to overlap an entirety of a surface of a substrate layer 7410 forming the second circuit region 7520.

In an embodiment, the FPCB 4400 or 5400A may include a bending portion 4430 or 5430 at least partially bending. The connecting layer 4420 or 5420 may not overlap the bending portion 4430 or 5430 and may be disposed on a surface of a part of a substrate layer 4410 or 5410 adjacent to the bending portion 4430 or 5430.

In an embodiment, the FPCB 8400 may include at least one protruding portion 8412 protruding from both ends in the width direction. In an embodiment, a guide hole 8412a may be formed in the protruding portion 8412. A connecting layer 8420 may be disposed between a plurality of substrate layers 8410 forming the protruding portion 8412.

An electronic device 101, 201, 301, 401, 901, 1001, 1101, or 1201 may include a housing including a component element disposed therein and an FPCB 4400, 5400A, 6400, 7400, 8400, 9400, 10400, 11400, or 12400 disposed in the housing, electrically connected to the component element, and at least partially bending in a longitudinal direction.

In an embodiment, the FPCB 4400, 5400A, 6400, 7400, 8400, 9400, 10400, 11400, or 12400 may include a plurality of substrate layers 4410, 5410, 6410, 7410, 8410, 9410, 10410, 11410, or 12410 disposed to overlap in a thickness direction T and including a circuit formed on surfaces thereof and at least one connecting layer 4420, 5420, 6420, 7420, 8420, 9420, 10420, 11420, or 12420 disposed on at least a portion between the plurality of substrate layers 4410, 5410, 6410, 7410, 8410, 9410, 10410, 11410, or 12410 and configured to connect a pair of substrate layers 4410, 5410, 6410, 7410, 8410, 9410, 10410, 11410, or 12410 adjacent to one another. In an embodiment, when viewed in the thickness direction T, the FPCB 4400, 5400A, 6400, 7400, 8400, 9400, 10400, 11400, or 12400 may include a first circuit region 4510, 5510, 6510, 7510, 8510, 9510, 10510, 11510, or 12510 in which a data line 4411-1, 5411-1, 6411-1, 7411-1, 8411-1, 9411-1, 10411-1, 11411-1, or 12411-1 for transmitting a data signal is positioned and a second circuit region 4520, 5520, 6520, 7520, 8520, 9520, 10520, 11520, or 12520 in which a power line 4411-2, 5411-2, 6411-2, 7411-2, 8411-2, 9411-2, 10411-2, 11411-2, or 12411-2 for transmitting a power signal is positioned. The at least one connecting layer 4420, 5420, 6420, 7420, 8420, 9420, 10420, 11420, or 12420 may be disposed not to overlap the first circuit region 4510, 5510, 6510, 7510, 8510, 9510, 10510, 11510, or 12510.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A wearable electronic device comprising:
a frame configured to accommodate at least one lens or at least one display;
a temple connected to an end of the frame; and
a flexible printed circuit board (FPCB) of which at least a portion is disposed in the temple and extending in a longitudinal direction,
wherein the FPCB comprises:
a plurality of substrate layers comprising at least one circuit line formed on a surface thereof and disposed to overlap in a thickness direction, and
at least one connecting layer disposed between the plurality of substrate layers and configured to connect surfaces of adjacent substrate layers, and
wherein the FPCB, when viewed in the thickness direction, comprises a first circuit region in which a data line for transmitting a data signal is formed, and the at least one connecting layer is disposed not to overlap the first circuit region.

2. The wearable electronic device of claim 1,
wherein the FPCB further comprises a second circuit region not overlapping the first circuit region and comprising a power line for transmitting a power signal, and
wherein, when the FPCB is viewed in the thickness direction, the at least one connecting layer overlaps the second circuit region.

3. The wearable electronic device of claim 2, wherein the at least one connecting layer is disposed to overlap an entirety of the second circuit region.

4. The wearable electronic device of claim 1,
wherein the FPCB further comprises a third circuit region comprising a ground line, and
wherein, when the FPCB is viewed in the thickness direction, the at least one connecting layer overlaps the third circuit region.

5. The wearable electronic device of claim 1,
wherein each of the plurality of substrate layers comprises at least one protruding portion protruding outward in a width direction perpendicular to the longitudinal direction, and
wherein, when the FPCB is viewed in the thickness direction, the at least one connecting layer overlaps the at least one protruding portion.

6. The wearable electronic device of claim 1, wherein the at least one protruding portion comprises at least one guide hole formed through the at least one protruding portion in the thickness direction.

7. The wearable electronic device of claim 1, wherein the FPCB is formed on the at least one protruding portion and comprises at least one via connected to ground.

8. The wearable electronic device of claim 1,
wherein the FPCB comprises at least one bending portion at least partially bending in the thickness direction, and
wherein the at least one connecting layer is disposed not to overlap the at least one bending portion.

9. The wearable electronic device of claim 8,
wherein, when viewed in the thickness direction, the FPCB comprises at least one connecting region in which the at least one connecting layer is positioned, and
wherein the at least one connecting region is disposed to be adjacent to the at least one bending portion.

10. The wearable electronic device of claim 9, wherein, on the FPCB, the at least one connecting region is positioned at each of both ends in a longitudinal direction of the at least one bending portion.

11. The wearable electronic device of claim 9,
wherein the FPCB comprises at least one bending portion at least partially bending in the thickness direction,
wherein the at least one connecting region comprises a first connecting region in which the at least one connecting layer is disposed not to overlap the at least one bending portion and a second connecting region in which the at least one connecting layer is disposed to overlap the at least one bending portion, and
wherein the second connecting region has a thinner thickness than the first connecting region.

12. The wearable electronic device of claim 11, wherein, in at least one connecting region disposed to be adjacent to the at least one bending portion, at least one pair of connecting layers disposed between different substrate layers have different areas.

13. The wearable electronic device of claim 1, wherein, based on a cross-section of the FPCB, the at least one connecting layer is disposed at each of both ends in a width direction of the FPCB.

14. The wearable electronic device of claim 1,
wherein at least a portion of the FPCB is disposed in a part in which the temple is connected to the frame, and
wherein the at least one connecting layer is disposed in at least a portion of a part of the FPCB disposed in the part in which the temple is connected to the frame.

15. The wearable electronic device of claim 1,
wherein the plurality of substrate layers comprises a first substrate layer, a second substrate layer, and a third substrate layer,
wherein the at least one connecting layer comprises:
at least one first connecting layer disposed on at least a portion between the first substrate layer and the second substrate layer, and
at least one second connecting layer disposed on at least a portion between the second substrate layer and the third substrate layer, and
wherein, when viewed in the thickness direction, the first connecting layer at least partially overlaps the second connecting layer.

16. A flexible printed circuit board (FPCB) comprising:
a plurality of substrate layers comprising a circuit line formed on surfaces thereof and disposed to overlap in a thickness direction; and
at least one connecting layer configured to connect at least a portion of the plurality of substrate layers,
wherein each of the plurality of substrate layers comprises:
a first circuit region comprising a data line for transmitting a data signal in a longitudinal direction of the FPCB, and
a second circuit region comprising a power line for transmitting a power signal in the longitudinal direction of the FPCB, and
wherein the at least one connecting layer is disposed not to overlap the first circuit region.

17. The FPCB of claim 16, wherein the at least one connecting layer is disposed to overlap an entirety of a surface of a substrate layer forming the second circuit region.

18. The FPCB of claim 17,
wherein the FPCB comprises a bending portion at least partially bending, and
wherein the at least one connecting layer does not overlap the bending portion and is disposed on a surface of a part of the substrate layer adjacent to the bending portion.

19. The FPCB of claim 16,
wherein the FPCB comprises at least one protruding portion protruding from both ends in a width direction,
wherein a guide hole is formed in the at least one protruding portion, and
wherein the at least one connecting layer is disposed between the plurality of substrate layers forming the at least one protruding portion.

20. An electronic device comprising:
a housing comprising a component element disposed therein; and
a flexible printed circuit board (FPCB) disposed in the housing, electrically connected to the component element, and at least partially bending in a longitudinal direction,
wherein the FPCB comprises:
a plurality of substrate layers disposed to overlap in a thickness direction and comprising a circuit formed on surfaces thereof, and
at least one connecting layer disposed on at least a portion between the plurality of substrate layers and configured to connect a pair of substrate layers adjacent to one another,
wherein, when viewed in the thickness direction, the FPCB comprises a first circuit region in which a data line for transmitting a data signal is positioned and a second circuit region in which a power line for transmitting a power signal is positioned, and
wherein the at least one connecting layer is disposed not to overlap the first circuit region.
